(19) United States
(12) Patent Application Publication
(10) Pub. No.: US 2005/0185463 A1
(43) Pub. Date: Aug. 25, 2005

(54) Nonvolatile memory and data processing system

(75) Inventors: Motoki Kanamori, Yokkaichi (JP); Shinichi Fukasawa, Kodaira (JP); Shigeo Kurakata, Tokorozawa (JP); Tetsuya Iida, Kodaira (JP); Shinsuke Asari, Akishima (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/058,672

(22) Filed: Feb. 16, 2005

(30) Foreign Application Priority Data
Feb. 20, 2004 (JP) 2004-043945

(51) Int. Cl. G11C 11/34

(52) U.S. Cl. 365/185.04

(57) ABSTRACT

The present invention provides a nonvolatile memory which includes a card controller, a reprogrammable nonvolatile memory and an IC card chip. The card controller is capable of outputting at least one of reset response information (ATR) outputted from the IC card chip in response to a reset instruction to the IC card chip and information indicative of an erase unit of a flash memory to the outside in response to a predetermined command supplied from outside. A card host is capable of causing the card controller to change an operating speed or operating frequency or the like of the IC card chip by reference to the ATR information. Upon reprogramming of memory information with respect to the reprogrammable nonvolatile memory, the card host is capable of sending write data equivalent to an amount commensurate with an erase unit to the nonvolatile memory by reference to the information indicative of the erase unit and giving write instructions.

### CROSS-REFERENCE TO RELATED APPLICATION

The present application claims priority from Japanese patent application No. 2004-043945 filed on Feb. 20, 2004, the content of which is hereby incorporated by reference into this application.

### BACKGROUND OF THE INVENTION

The present invention relates to a nonvolatile memory having a nonvolatile information storage function, a nonvolatile memory having a security function effected on memory information together with a nonvolatile information storage function, a data processing system such as a host device with the nonvolatile memory inserted therein, and to a technique effective when applied to, for example, a memory card having a flash memory chip, an IC card microcomputer chip and a controller chip.

Interface terminals and transfer protocols between devices of an IC card have been described in a document 1 (ISO/IEC 7816-3 Second edition (1997-12-15)). For example, ATR (Answer To Reset), etc. have been described therein. ATR is assumed to be a value for indicating a communication protocol sent from the IC card to the corresponding interface device after reset processing, as a response to the reset processing. Command specs used for information exchange of an IC card have been described in a document 2 (ISO/IEC 7816-4 First edition (1995-09-01)).

A document 3 (Unexamined Patent Publication No. 2003-22216) describes a memory card which has a flash memory chip, an IC card chip capable of executing security processing, and a controller chip that controls accessing or the like to the flash memory chip and the IC card chip according to a request issued from a host, and in which the controller chip can obtain access to both the flash memory chip and the IC card chip according to the request issued from the host.

### SUMMARY OF THE INVENTION

The present inventors have discussed communication capability between a memory card and a card host. The first relates to an application to the use of a mobile of a flash memory card equipped with a security function based on an IC card chip.

When an IC card is reset between the IC card and a card host, the card host normally directly reads ATR information as a reset response outputted from the IC card, performs necessary communication settings using the ATR information, and subsequently carried out command processing based on the description of the document 2 on the set communication conditions. There is also known one which uses a proper value dependent on an OS (Operating System) of an IC card, contained in ATR information, depending on an application of a card host. In view of an application which makes use of an IC card with a mobile terminal as a target, the necessity for the control form that a communication speed and a computing speed are made fast where high-speed processing based on an IC card is required, whereas where it is not required, power consumption is restrained and the life of a battery is made long-lived, has been found out.

However, it is desired that when the memory card is equipped with the security function based on the IC card, a controller chip is not deeply associated with the processing of the IC card in view of maintenance of security. Therefore, a controller performs reset and communication settings to the IC card. Further, the transfer of data between the card host and the IC card chip after completion of the communication settings is carried out by providing the controller with a new or novel card command such as CMD51, CMD52 or the like. The new card command is a command accompanied by an IC card command or the like which gives instructions for command processing based on ISO7816. A card controller having received the new memory card command CMD52 therein supplies an IC card command corresponding to information for security processing attached to the command to the IC card chip. The card controller having received the memory card command CMD51 supplies response data or the like outputted from the IC card in response to the IC card command to the card host.

In such a case, ATR information directly transferred between the conventional card host and the IC card cannot be read. That is, the reset and communication settings to the IC card chip are performed by the card controller, and the ATR information is not outputted to the card host. In the case of the new card commands CMD51 and CMD52 subsequent to the communication settings, the ATR information cannot be read. Thus, the card host involves a problem in terms of compatibility with the IC card in respect of processing depending on an application or the like which refers to the ATR information. Further, since the card host is not able to acquire the ATR information from the memory card having the IC card chip, the communication setting of an operating frequency or the like of the IC card chip cannot be changed according to the application of the card host and the contents of processing by the IC card chip, thereby causing restrictions on mobile uses. This results from the fact that communication capability is insufficient between a conventional memory card equipped with an IC card function and a card host in a command system of the conventional memory card.

The second relates to an increase in rewrite or reprogrammable stress applied to each flash memory and degradation of a write transfer rate due to the number of transfers of data from a card host at writing where erase units of flash memories mounted in memory cards are different between the memory cards. In general, the flash memories mounted in the memory card are not unified in terms of the erase unit due to the difference in construction between memory arrays and the difference in memory capacity as in the case of AND, NAND and AG-AND. As to the difference in erase unit, a controller of a memory card controls erase processing according to the difference. However, the flash memories are physically different in the number of times that erasing is done, depending on the number of write data transferred from the card host with one write command. When the card host issues a write command twice with write data of 1024 bits to carry out rewriting of 2048 bits when the erase unit is 2048 bits, for example, stress due to the application of a high voltage for erasure becomes twice as compared with the case in which the card host issues a write command once with write data of 2048 bits. A memory card per se equipped with flash memories large in rewrite unit is further large in stress (number of erasures) and overhead at writing also increases. This results from insufficiency of communication capability that a command system of a conventional memory card is not provided with communication means for recognizing an erase unit of a nonvolatile memory built therein from outside.

An object of the present invention is to improve communication capability between a nonvolatile memory or nonvolatile memory device like a memory card equipped with a nonvolatile memory like a security controller or flash memory chip like an IC card chip, and a data processing system.

Another object of the present invention is to make it possible to change an operating speed and power consumption of a security controller employed in a nonvolatile memory like a memory card equipped with a security controller like an IC card chip.

A further object of the present invention is to externally enable satisfactory initialization of transfer efficiency of write data, which is based on an erase or initialization unit of a storage area in a nonvolatile memory like a flash memory mounted in a memory card and which less reduces rewrite stress.

The above, other objects and novel features of the present invention will become apparent from the description of the present specification and the accompanying drawings.

Summaries of representative ones of the inventions disclosed in the present application will be explained in brief as follows:

[1] A nonvolatile memory like a memory card comprises an interface controller, a reprogrammable nonvolatile memory, and a security controller which performs security processing of data. The interface controller is capable of outputting at least one of reset response information (ATR) outputted by the security controller in response to a reset instruction to the security controller and information (F_CODE, F_CNT) indicative of an erase unit of a storage area of the reprogrammable nonvolatile memory to the outside in response to a predetermined first command supplied to the interface controller from outside. By outputting reset response information to the outside in response to an external command, a data processing system like a card host that receives it, is capable of causing an interface controller to change an operating speed or operating frequency or the like of a security controller by reference to the reset response information. By outputting information indicative of an erase unit to the outside in response to an external command, the data processing system like the card host that receives it, is capable of, upon reprogramming of memory information with respect to a reprogrammable nonvolatile memory, sending write data equivalent to an amount commensurate with an erase unit of a storage area to a nonvolatile memory by reference to the information indicative of the erase unit and giving write instructions.

As a specific form of the present invention, the interface controller is capable of changing the frequency of a clock signal supplied to the security controller in response to a frequency setting command.

As another specific form of the present invention, the interface controller extracts security processing information contained in a second command supplied from outside, in response to the second command and supplies the same to the security controller. The interface controller outputs the result of security processing by the security controller to the outside in response to a third command supplied from outside. The interface controller is capable of instructing the security controller to perform security processing without intruding into the construction of the security controller.

As a further form of the present invention, the interface controller has a volatile memory circuit which latches at least the one information in response to a reset command of the nonvolatile memory and outputs the one information held in the memory circuit to the outside of a memory card in response to the predetermined first command. At this time, at least the one information held in the volatile memory circuit may be initially stored in the reprogrammable nonvolatile memory. Accessing to the inside of the security controller may not be performed each time. When a plurality of reprogrammable nonvolatile memories exist, the reprogrammable nonvolatile memories may not be accessed plural times to acquire device codes or the like from the respective reprogrammable nonvolatile memories.

As a still further form of the present invention, the predetermined first command has a command code different from the reset command of the nonvolatile memory. As another form, when a command code of the reset command of the nonvolatile memory is allocated to the predetermined first command, the interface controller outputs at least the one information to the outside following a response to reset processing. As a further form, when a command code of a read command relative to a predetermined register like a card identification register or a card characteristic register held in the interface controller is allocated to the predetermined first command, the interface controller outputs at least the one information to the outside, following the output of the information held in the register or while the information is being allocated to a reserved area of the register.

As a still further form of the present invention, the reset response information includes an operation limit frequency and historical byte information of the security controller. The information indicative of the erase unit of the storage area is a device code indicative of the type of reprogrammable nonvolatile memory, or number-of-data information corresponding to an erase unit, generated based on the device code.

[2] A data processing system is mountably provided with the nonvolatile memory. In the data processing system, the predetermined first command for outputting the reset response information is outputted to the nonvolatile memory, the reset response information outputted from the nonvolatile memory is inputted in response to the predetermined first command, and the setting of an operating frequency of the security controller can be changed by reference to the inputted reset response information. By outputting reset response information to the outside in response to an external command, the data processing system like the card host that receives it, is capable of causing an interface controller to change an operating speed or operating frequency or the like of the security controller by reference to the reset response information.

A data processing system like a card host according to another form is mountably provided with the nonvolatile memory. In the data processing system, the predetermined first command for outputting the information indicative of the erase unit of the storage area is outputted to the nonvolatile memory, the information indicative of the ease unit of the storage area, which is outputted from the nonvolatile memory, is inputted in response to the predetermined first command, and the number of transfers of write data to the nonvolatile memory is set for each erase unit, based on the inputted information indicative of the erase unit. By outputting information indicative of an erase unit to the outside in response to an external command, the data processing system like the card host that receives it, is capable of, upon reprogramming of memory information with respect to a reprogrammable nonvolatile memory, sending write data equivalent to an amount commensurate with an erase unit of a storage area to a nonvolatile memory by reference to the information indicative of the erase unit and giving write instructions.

[3] A nonvolatile memory like a memory card comprises an interface controller, and a reprogrammable nonvolatile memory. The interface controller is capable of outputting information indicative of an erase unit of a storage area of the reprogrammable nonvolatile memory to the outside in response to a predetermined command supplied to the interface controller from outside. By outputting information indicative of an erase unit to the outside in response to an external command, a data processing system like a card host that receives it, is capable of, upon reprogramming of memory information with respect to a reprogrammable nonvolatile memory, transmitting write data equivalent to an amount commensurate with an erase unit of a storage area to a nonvolatile memory by reference to the information indicative of the erase unit and giving write instructions.

As a specific form of the present invention, when the same command code as the reset command of the nonvolatile memory is allocated to the predetermined command, the interface controller outputs the information indicative of the erase unit to the outside following a response to reset processing. As another form, when a command code identical to a read command relative to a predetermined register like a card identification register or a card characteristic register held in the interface controller is allocated to the predetermined command, the interface controller outputs the information indicative of the erase unit to the outside, following the output of the information retained in the register or while it is being allocated to a reserved area of the corresponding register.

As another specific form of the present invention, the information indicative of the erase unit is a device code indicative of the type of reprogrammable nonvolatile memory, or number-of-data information corresponding to an erase unit of a storage area, generated based on the device code. The interface controller acquires a device code indicative of the type of reprogrammable nonvolatile memory from the reprogrammable nonvolatile memory, acquires an operation limit frequency of the reprogrammable nonvolatile memory based on the acquired device code, and outputs the operation limit frequency to the outside in response to the predetermined command. The interface controller is capable of changing the frequency of a clock signal supplied to the reprogrammable nonvolatile memory in response to a frequency setting command.

Advantageous effects obtained by representative ones of the inventions disclosed in the present application will be explained in brief as follows:

Since the output of reset response information to the outside and the output of information indicative of an erase unit can be carried out, it is possible to improve communication capability between a nonvolatile memory like a memory card equipped with a reprogrammable nonvolatile memory like a security controller or flash memory chip like an IC card chip, and a data processing system like a card host.

Since the output of reset response information to the outside is enabled, it is possible to change an operating speed and power consumption of a security controller employed in a nonvolatile memory like a memory card equipped with the security controller like an IC card chip.

Since the output of information indicative of an erase unit to the outside is enabled, it is possible to externally effect access control low in rewrite stress and good in transfer efficiency of write data, which is based on an erase unit, on a storage area like an erase unit in a reprogrammable nonvolatile memory like a flash memory mounted to a memory card.

### BRIEF DESCRIPTION OF THE DRAWINGS

FIG. 1 is a block diagram showing an internal configuration of an MMC used as a nonvolatile memory or storage device to which the present invention is applied;

FIG. 2 is an explanatory diagram showing command protocols of a secure read command (CMD51) and a secure write command (CMD52);

FIG. 3 is an explanatory diagram illustrating several forms of ATR information read commands;

FIG. 4 is an explanatory diagram illustrating a first embodiment for realizing a function based on an ATR information read command CMD50;

FIG. 5 is an explanatory diagram illustrating a second embodiment for realizing a function based on an ATR information read command CMD50;

FIG. 6 is an explanatory diagram illustrating a third embodiment for realizing a function based on an ATR information read command CMD50;

FIG. 7 is an explanatory diagram showing an operation example in which a host device refers to ATR information;

FIG. 8 is an explanatory diagram depicting another operation example in which a host device refers to ATR information;

FIG. 9 is an explanatory diagram illustrating a further example in which a host device refers to ATR information;

FIG. 10 is an explanatory diagram showing a still further example in which a host device refers to ATR information;

FIG. 11 is an explanatory diagram depicting a still further example in which a host device refers to ATR information;

FIG. 12 is an explanatory diagram illustrating several forms of device code read commands stored in a flash memory chip as information indicative of erase units;

FIG. 13 is an explanatory diagram illustrating a first embodiment for realizing a function based on a device code read command CMD49;

FIG. 14 is an explanatory diagram illustrating a second embodiment for realizing a function based on a device code read command CMD49;

FIG. 15 is an explanatory diagram illustrating a third embodiment for realizing a function based on a device code read command CMD49;

FIG. 16 is an explanatory diagram illustrating the first half of the operation of transferring, with one command, data of 1 KB to an MMC1 to which a flash memory with an erase unit of 2 KB is mounted, and writing data of 2 KB in total therein;

FIG. 17 is an explanatory diagram illustrating the latter operation following the operation shown in FIG. 16;

FIG. 18 is an explanatory diagram showing an example illustrative of comparisons between the operation of transferring write data of 1 KB with one write command and performing writing equivalent to 16 KB in total, and the operation of transferring write data of 2 KB with one write command and performing writing equivalent to 16 KB in total;

FIG. 19 is an explanatory diagram showing an example of the operation of causing a host device to grasp an erase unit of a flash memory from a flash device code and optimizing the number of transfers of write data;

FIG. 20 is an explanatory diagram depicting the operation of transferring, with one command, data of 2 KB to an MMC1 to which a flash memory with an erase unit of 2 KB is mounted;

FIG. 21 is an explanatory diagram showing an example in which a controller chip has the function of analyzing the optimum rewrite or reprogrammable unit based on a read device code;

FIG. 22 is a timing chart for describing a write operation based on the result of analysis of the optimum rewrite unit; and

FIG. 23 is an explanatory diagram showing an example in which a device code is used to set the frequency of each flash memory chip.

### DETAILED DESCRIPTION OF THE PREFFERED EMBODIMENTS

<<MMC>>

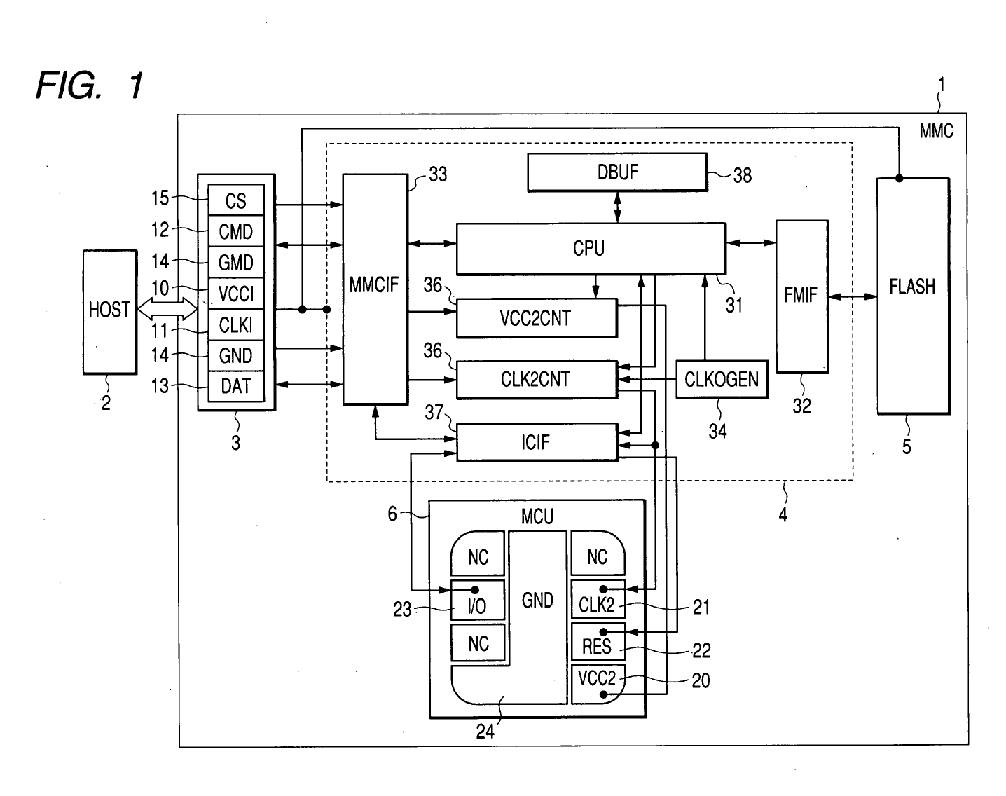

FIG. 1 is a diagram showing an internal configuration of a MultiMediaCard (which is a registered trademark of InfineonTechnologiesAG. It is hereinafter abbreviated as “MMC”) used as a nonvolatile memory to which the present invention is applied. The MMC1 may preferably be based on MMC specs. The MMC1 has a security processing function which performs cipher computations necessary for confidential data protection and personal authentication or the like on the basis of memory card commands based on MMC specs, issued from a host device (or card host) used as a data processor connected to the MMC1.

The host device 2 corresponds to, for example, each of a cellular phone, a personal digital assistant (PDA), a personal computer, a music playback (and recording) equipment, a camera, a video camera, an automatic teller machine, a public terminal and a settlement terminal or the like.

The MMC1 includes an MMC external terminal 3, a controller chip 4 used as an interface controller, a flash memory chip (FLASH) 5 used as a nonvolatile memory and an IC card chip (MCU) 6 used as a security controller. The flash memory chip 5 is a memory chip in which a nonvolatile semiconductor memory is configured as a storage medium. The flash memory chip 5 is capable of performing reading/writing of data in accordance with a flash memory command. The MMC external terminal 3 comprises seven terminals of a power (VCC2) supply terminal 10, a clock (CLK1) input terminal 11, a command (CMD) input/output terminal 12, a data (DAT) input/output terminal 13, a ground (GND) terminal 14 and a chip selection (CS) terminal 15 or the like in order to swap information with an external host device 2. The MMC specs define two types of an MMC mode and an SPI mode as operation modes for the MMC1. The MMC external terminal 3 varies according to the operation modes in usage.

The controller chip 4 is a microcomputer chip which is connected to the MMC external terminal 3, the flash memory chip 5 and the IC card chip 6 and controls these.

The IC card chip 6 is a microcomputer chip for being embedded into a plastic substrate of an IC card. External terminals, an electric signal protocol and commands contained in the IC card chip 6 are based on the ISO/IEC7816 standard. The external terminals of the IC card chip 6 include a power (VCC2) supply terminal 20, a clock (CLK2) input terminal 21, a reset (RES) input terminal 22, an input/output (I/O) terminal 23 and a ground (GND) terminal 24. An NC terminal is a spare terminal to be used for the future. The controller chip 4 issues an IC card command to the IC card chip 6 through the corresponding external terminal of the IC card chip 6 to thereby perform a computation necessary for security processing required from the external host device 2.

Although not shown in the drawing in particular, the IC card chip 6 includes a CPU (micon) for performing a computing process, a ROM (Read Only Memory) for storing data (including programs), a RAM (Random Access Memory), an EEPROM (Electrically Erasable Programmable ROM), a cipher coprocessor which constitutes an encryptor for performing a process related to encryption/decryption, and a serial interface which performs transmission/reception of data to and from the outside. They are connected to one another by buses.

The cipher coprocessor executes a security process in accordance with a command issued from the host device 2. Incidentally, the CPU may execute the security process using a program (software) in place of the cipher coprocessor (hardware). The security process is executed when, for example, data is written into a storage area lying in the IC card chip 6 or read from the storage area in the IC card chip 6.

The flash memory chip 5 has a nonvolatile storage element. In general, the storage capacity of the EEPROM of the IC card chip 6 is smaller than that of the flash memory chip 5. However, the storage capacity of the EEPROM may be the same as that of the flash memory chip 5 or may be larger than it.

It is desired that the product already authenticated by the evaluation/authentication agency of ISO/IEC15408 corresponding to the international standard equivalent to criterion for security evaluation is used for the IC card chip 6. When an IC card having the function of performing a security process is generally used in actual electronic banking service or the like, the IC card needs to be evaluated and authenticated by the ISO/IEC15408 evaluation/authentication agency. When the MMC1 is realized by adding the function of performing the security process to MMC and it is used in the actual electronic banking service or the like, the MMC1 also needs to be evaluated and authenticated by the ISO/IEC15408 evaluation/authentication agency in like manner. In the present invention, the MMC1 obtains the security processing function by having such a structure that the IC card chip 6 already authenticated by the evaluation/authentication agency is built therein and the security process is executed using the IC card chip 6. Accordingly, the MMC1 is capable of easily meeting the security evaluation criterion based on ISO/IEC15408 and shortening a development period for adding the security processing function to the MMC. However, an IC card chip that does not belong to the products already authenticated by the ISO/IEC15408 evaluation/authentication agency shall not be diverted. An IC card chip corresponding to such a required security strength of services as provided by the IC card chip may be used.

The MMC1 may preferably have an external interface based on the MMC specs. The MMC1 needs to accept a command for executing a security process in addition to a standard memory card command (command for obtaining access to flash memory chip) through one type of external interface. The controller chip 4 has the function of selecting a chip to be accessed, according to whether the command received by the MMC1 corresponds to the standard memory card command or the command for executing the security process and distributing command processing. In the present example, the controller chip 4 is capable of selecting the flash memory chip 5 when it receives the standard memory card command and issuing a flash memory command thereto to thereby perform reading/writing of host data. The controller chip 4 is capable of selecting the IC card chip 6 when it receives the command for executing the security process, and issuing an IC card command thereto to thereby execute the security process. Further, in order to enhance an ability to communicate with the host device 2, the controller chip 4 has the function of outputting ATR information outputted from the corresponding IC card chip to the outside in response to reset instructions and the function of outputting information indicative of the erase unit of the flash memory chip 5 to the outside. However, an external interface other than the external interface based on the MMC specs shall not be diverted. The controller chip may be one based on an external interface that exists at present or will exist in the future.

Except for the ground terminal 24, the external terminals of the IC card chip 6, i.e., the power supply terminal 20, the clock input terminal 21, the reset input terminal 22, and the input/output terminal 23 are connected to the controller chip 4.

The controller chip 4 controls the supply of power and a clock to the IC card chip 6 through the power supply terminal 10 and the clock input terminal 11. According to the present embodiment, when no security process is requested from the host device 2, the controller chip 4 is able to stop the supply of the power and clock to the IC card chip 6 and thereby reduce power consumption of the MMC1.

In order to bring the IC card chip 6 supplied with no power to a state of being able to receive the IC card command, there is a need to first start the supply of power to the IC card chip 6 and perform reset processing thereon. That is, the controller chip 4 has the function of starting the supply of power to the IC card chip 6 through the power supply terminal when the MMC1 has received the command for executing the security process from the host device 2. Also, the controller chip 4 has the function of executing the reset processing of the IC card chip 6 through the reset input terminal when the MMC1 has received the command for executing the security command from the host device 2. According to it, the controller chip 4 is capable of stopping the supply of power to the IC card chip 6 until it receives the command for executing the security process. Thus, it is possible to reduce power consumption of the MMC1.

The controller chip 4 has the function of generating a clock signal to be supplied to the IC card chip 6 through the clock input terminal of the IC card chip 6 inside the MMC1 and controlling its frequency, supply start timing and supply stop timing.

The controller chip 4 includes a CPU 31, a flash memory I/F controller (FMIF) 32, an MMC1/F controller (MMCIF) 33, a CLK0 oscillator or generator (CLK0GEN) 34, a VCC2 controller (VCC2CNT) 35, a CLK2 controller (CLK2CNT) 36, an IC card I/F controller (ICIF) 37, and a data buffer 38. These constituent elements or components 31 through 38 are operated by electric power supplied from the host device 2 through the VCC1 terminal 10 and the GND1 terminals 14 and 14. The MMCI/F controller 33 is connected to the CS terminal 15, CMD terminal 12, CLK1 terminal 11 and DAT terminal 13 and is a logic circuit which controls an interface for allowing the MMC1 to swap information with the host device 2 through those terminals.

The CPU 31 is connected to the MMCI/F controller 33 and controls the MMCI/F controller 33. When the MMCI/F controller 33 receives a memory card command from the host device 2 through the CMD terminal 12, the MMCI/F controller 33 transmits a response to the host device 2 via the CMD terminal 12 to transfer a result indicative of whether the reception of the command has succeeded, to the host device 2. The CPU 31 interprets the received memory card command and executes processing corresponding to the contents of the command. When the CPU 31 needs to perform transmission/reception of data to and from the host device 2 through the DAT terminal 13 according to the contents of the command, the CPU 31 sends data to the MMCI/F controller 33 and acquires the data from the MMCI/F controller 33. The CLK0 generator 34 is connected to the CPU 31 and supplies a drive clock for operating the CPU 31.

The flash memory chip 5 is of the memory chip in which the nonvolatile semiconductor memory is configured as the storage medium. The flash memory chip 5 is operated by electric power supplied from the host device 2 through the VCC1 terminal 10 and the GND1 terminal 14. The flash memory chip 5 has a write function for storing the input data into the nonvolatile semiconductor memory in accordance with an external flash memory command and a read function for outputting the data stored in the same memory to the outside. The flash memory I/F controller 32 is a logic circuit for issuing a flash memory command to the flash memory chip 5 and transferring data inputted/outputted in accordance with the flash memory command. The CPU 31 controls the flash memory I/F controller 32 to cause the flash memory chip 5 to execute its data write function and read function. When it is necessary to write the data received from the host device 2 into the flash memory chip 5 and transmit the data stored in the flash memory chip 5 to the host device 2, the CPU 31 controls the transfer of data between the flash memory I/F controller 32 and the MMCI/F controller 33.

The ground terminal 24 of the IC card chip 6 is connected to the GND terminal 14 of the MMC external terminal 3. The VCC2 terminal 20 of the IC card chip 6 is connected to the VCC2 controller 35 of the controller chip 4. The RST terminal (reset input terminal) 22 of the IC card chip 6 and the I/O terminal (data input/output terminal) 23 thereof are connected to the IC card I/F controller 37 of the controller chip 4. The CLK2 terminal (clock input terminal) 21 of the IC card chip 6 is connected to the CLK2 controller 36 of the controller chip 4.

The VVC2 terminal 20 is a power supply or power terminal for supplying electric power to the IC card chip 6. The VCC2 controller 35 is a circuit which generates a VCC2 voltage and controls the start and stop of supply of electric power to the VCC2 terminal 20 by a switch circuit using a MOS-FET element. The VCC2 controller 35 is connected to the CPU 31 and the CPU 31 is capable of controlling the start and stop of the electric power to the VCC2 terminal 20. When no IC card chip 6 is used, the CPU 31 is able to stop the supply of the electric power to the VCC2 terminal 20. The MMC1 stops the supply of electric power to the IC card chip 6 to thereby enable savings in electric power consumed thereby.

The CLK2 terminal 21 is a terminal for inputting the clock signal to the IC card chip 6. The CLK2 controller 36 is a circuit which supplies a clock to the CLK2 terminal 21. The CLK2 controller 36 generates the clock signal to be supplied to the CLK2 terminal 21, based on the clock signal supplied from the CLK0 generator 34. The CLK2 controller 36 is connected to the CPU 31 and is capable of controlling the start and stop of the clock to the CLK2 terminal 21 through the CPU 31. The IC card chip 6 has no drive clock generator thereinside. Therefore, the IC card chip 6 is operated by being supplied with a drive clock through the CLK2 terminal 21. When the CLK2 controller 36 stops the supply of the clock to the CLK2 terminal 21, the operation of the IC card chip 6 is stopped and hence power consumption of the IC card chip 6 can be reduced. If the supply of the electric power to the VCC2 terminal 20 is kept at this time, then an internal state of the IC card chip 6 is maintained.

Assuming now that the frequency of the clock signal supplied to the CLK2 terminal 21 is F2, the frequency of the clock signal supplied from the CLK0 generator 34 is FO, and P and Q are positive integers, the CLK2 controller 36 generates such a clock signal that F2=(P/Q)*FO is reached, and supplies it to the CLK2 terminal 21. The values of P and Q can be set by the CPU 31. If P is set large and F2 is made large, then the internal processing of the IC card chip 6 can be driven at higher speed. If Q is set large and F2 is made small, then the internal processing of the IC card chip 6 is driven at lower speed so that the power consumption of the IC card chip 6 can be reduced. A drive clock frequency for the IC card chip 6 needs to be set to within such an allowable frequency range that the IC card chip 6 can be properly operated. Therefore, the CLK2 controller 36 avoids the setting of the values of such P and Q that the value of F2 is out of the allowable frequency range.

The I/O terminal 23 is an input/output terminal used when an IC card command is inputted to the IC card chip 6 and the IC card chip 6 outputs an IC card response. The IC card I/F controller 37 is connected to the I/O terminal 23 and is a circuit which performs the signal transmission of the IC card command through the I/O terminal 23 and the signal reception of the IC card response therethrough. The IC card I/F controller 37 is connected to the CPU 31, and the CPU 31 controls a procedure for transmission/reception of the IC card command and the IC card response by the IC card I/F controller 37, sets IC card command data to be transmitted to the IC card I/F controller 37, and acquires the received IC card response or the like from the IC card I/F controller 37. The IC card I/F controller 37 is supplied with the clock from the CLK2 controller 36, and the IC card command and IC card response are synchronized with the clock signal supplied to the CLK2 terminal 21 in bit units and transmitted and received through the I/O terminal 23. The RST terminal 22 is a terminal which inputs a reset signal when the IC card chip 6 is reset. The IC card I/F controller 37 is connected to the RST terminal 22 and is capable of transmitting the reset signal to the IC card chip 6 according to instructions issued from the CPU 31.

<<Standard Memory Card Command>>

A standard memory card command based on the MMC will be explained. The command has a command field of 6 bytes. The leading one byte is defined s a command code (leading two bits are fixed to “01”), the midway 4 bytes are defined as arguments used in parameter designation or the like, and the final one byte is defined as CRC (Cyclic Redundancy Check). The MMC sends back a response to the host device each time a command is issued. When, for example, a reset startup command such as CMD1 is issued, the MMC1 is internally initialized. At this time, the controller chip 4 gives a reset instruction to the reset terminal 22 of the IC card chip 6. When the reset instruction is given to the reset terminal 22, the IC card chip 6 is internally initialized and thereafter outputs ATR information to the controller chip 4 as reset response information. The ATR information contains an operating limit frequency of the IC card chip 6, historical bytes, etc. The historical bytes contain version information of an OS (Operating System), attribute information of an application program, etc. held in the IC card chip 6. The controller chip 4 performs communication settings of the frequency of a clock CLK2, etc. by referring to the ATR information received from the IC card chip 6. Thereafter, when the host device issues a read-system command such as CMD17, the MMC1 sends back a response containing a command index and a card status, corresponding to the accepted command to the host device, and outputs data read from the flash memory chip to the host device. When a write-system command such as CMD 24 is issued, the MMC1 sends back a response containing a command index and a card status, corresponding to the accepted command to the host device, and writes write data supplied from the host device into the corresponding flash memory chip.

<<Security Processing Command>>

A security processing command for causing the IC card chip 6 to execute a security process is realized by an IC card access command. Described specifically, the security processing command is composed principally of a secure read command (CMD51) and a secure write command (CMD52), which avail of empty or free command codes of the standard memory card command. Their command protocols are similar to a read system command and a write system command of the standard memory card command.

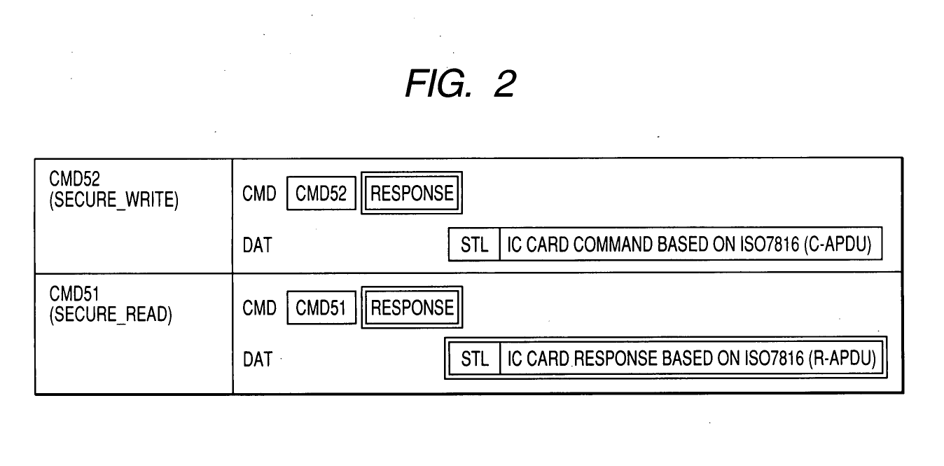

Command protocols for the secure read command (CMD51) and the secure write command (CMD52) are shown in FIG. 2. Signal information corresponding to the described position of CMD means signal information inputted/outputted via the CMD terminal. Signal information corresponding to the described position of DAT means signal information inputted/outputted via the DAT terminal. In the figure, the direction of supply of information described within a single or onefold frame corresponds to the direction of the MMC1 as viewed from the card host, and the direction of supply of information described within a double frame corresponds to the direction of the card host as viewed from the MMC1. In the case of the secure write command (CMD52), the number of transfer data bytes STL and an IC card command (C-APDU) based on ISO7816 are contained in write data. When the CPU 31 of the controller chip 4 identifies the CMD52 from a command code of a command supplied thereto, the CPU 31 supplies an IC card command (C-APDU) of bytes indicated by the number of transfer data bytes STL, of write data coming with it from the ICIF 37 to the input/output terminal 23 of the IC card chip 6. In the case of the secure read command (CMD51), the number of transfer data bytes STL, and an IC card response (R-APDU) based on ISO7816 are contained in read data. The IC card response (R-APDU) corresponds to data subjected to security processing by the IC card. That is, it shows a result processed in accordance with the IC card command (C-APDU) supplied to the IC card, based on the previously-issued secure write command, and is indicative of data held in a data buffer of the ICIF 37. When the CPU 31 of the controller chip 4 identifies the CMD51 from the command code of the command supplied thereto, the CPU 31 outputs the IC card response (R-APDU) to the outside of the MMC1 with the number of data bytes STL of the IC card response (R-APDU) as the head.

It is not possible to read ATR information from the IC card chip 6 and output the same to the outside of the MMC1 in the case of the secure read command (CMD51).

<<ATR Information Read Command>>

As described in the section 6.4Anser-to-Reset structure of “ISO/IEC 7816-3:1997(E), ATR information used as reset response information contains a rate of an operating clock for determining an operating limit frequency of an IC card chip, a baud rate of input/output data, and historical byte information of the IC card chip, etc. The MMC1 has a command (ATR information read command) for allowing the ATR information to be read outside the MMC1, as a command for enhancing the capability of communication with the host device.

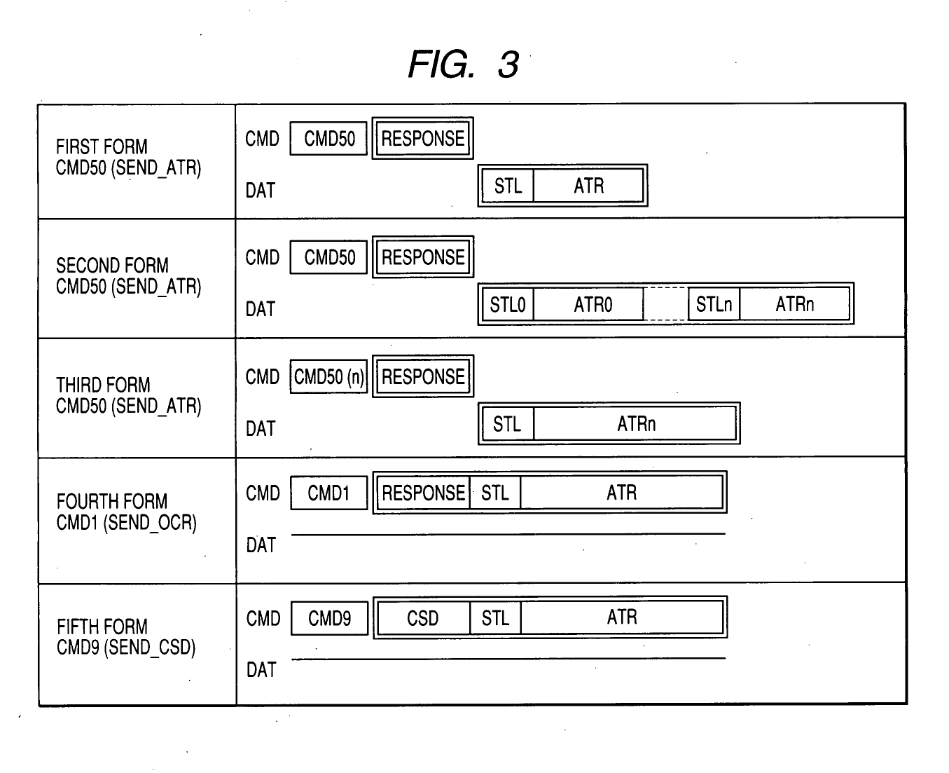

Several forms of ATR information read commands are illustrated in FIG. 3. The first form of the ATR information read command is defined as a new command (also called simply ATR information read command CMD50) which avails of an empty or free command code of a standard memory card command. Signal information corresponding to the described position of CMD in the column of the ATR information read command CMD50 means signal information inputted/outputted via the CMD terminal. Signal information corresponding to the described position of DAT means signal information inputted/outputted via the DAT terminal. In the figure, the direction of supply of information described in a single or onefold frame corresponds to the direction of the MMC1 as viewed from the card host. The direction of supply of information described in a double frame corresponds to the direction of the card host as viewed from the MMC1. When the command CMD50 is inputted to the CMD terminal, a response is sent back in response to the command CMD50 and ATR information is outputted to the DAT terminal following the number of transfer data bytes STL. The ATR information read command CMD50 is set assuming that the IC card chip mounted to the MMC1 is single.

The second form of the ATR information read command is set assuming that the number of IC card chips mounted to the MMC1 is two or more. A data output from the DAT terminal, which responds to the CMD50, is constituted as a sequential output of the number of data bytes STL and ATR information for each IC card chip. The number of IC card chips 6 is recognized by the controller chip 4.

The third form of the ATR information read command is set so as to read ATR information on an IC card chip designated by a parameter where the number of the IC card chips mounted to the MMC1 is two or more. The parameter is information which designates to what number of IC card chips the IC card chip corresponds. The controller chip 4 outputs ATR information on the IC card chip 6 corresponding to the number designated by the parameter with respect to the number of the IC card chips 6 from the DAT terminal.

The fourth form of the ATR information read command has a command code identical to the existing reset startup command such as CMD1. The controller chip 4 outputs the number of transfer data bytes STL and ATR information to the CMD terminal following a response for initializing processing.

The fifth form of the ATR information read command has a command code identical to the existing register read command such as CMD9. The controller chip 4 outputs the number of transfer data bytes STL and ATR information to the CMD terminal while following the output of a register value or being allocated to a reserved area of each register. Registers intended for read by CMD9 include a card identification register (CID) that holds a manufacturer's number and a card's serial number, etc., and a card characteristic data register (CSD) that holds information such as an access time and a card capacity, etc.

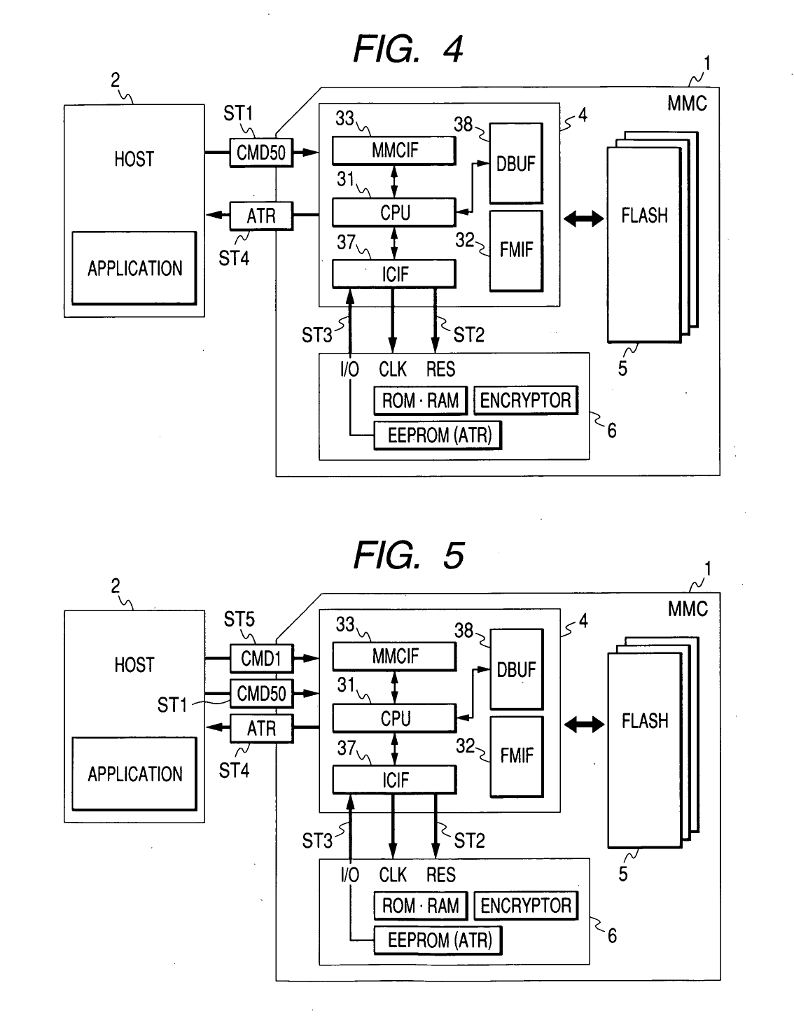

A first embodiment for realizing a function based on an ATR information read command CMD5 is illustrated in FIG. 4. The first embodiment aims to effect reset processing on an IC card chip 6 when the ATR information read command CMD50 is accepted, store ATR information outputted from the IC card chip 6 in accordance with its reset processing into a data buffer 38 and output the stored ATR information to a host device 2. That is, when the ATR information read command CMD50 is issued from the host device 2 (ST1), a controller chip 4 inputs it therein and decodes it through a CPU 31, and gives instructions for reset to a RES terminal of the IC card chip 6 through an ICIF 37 (ST2). Thus, the IC card chip 6 is initialized so that ATR information is outputted therefrom, which in turn is stored in the data buffer 38 from the ICIF 37 through the CPU 31 (ST3). The stored ATR information is outputted from an MMCIF 33 to the host device 2.

A second embodiment for realizing a function based on an ATR information read command CMD50 is illustrated in FIG. 5. The second embodiment aims to store ATR information outputted by reset processing of an IC card chip 6 upon power-on reset of an MMC1 into a data buffer 38 and output the ATR information from the data buffer 38 to a host device 2 when the ATR information read command CMD50 is accepted. That is, when a reset startup command CMD1 is issued from the host device 2 (ST5), a controller chip 4 inputs it therein and decodes it through a CPU 31, and gives instructions for reset to a RES terminal of the IC card chip 6 through an ICIF 37 (ST2). Consequentially, the IC card chip 6 is initialized so that ATR information is outputted therefrom. Therefore, the ATR information is stored and held in the data buffer 38 from the ICIF 37 through the CPU 31 (ST3). Thereafter, when the ATR information read command CMD50 is issued from the host device 2 (ST1), the controller chip 4 inputs it therein, and decodes it through the CPU 31 and outputs the ATR information stored in the data buffer 38 to the host device 2 through an MMICF 33 (ST4). In the second embodiment as compared with the first embodiment, latency time from the issuance of the ATR information read command CMD50 from the host device 2 to the output of the ATR information to the host device 2 through the MMCIF 33 becomes short.

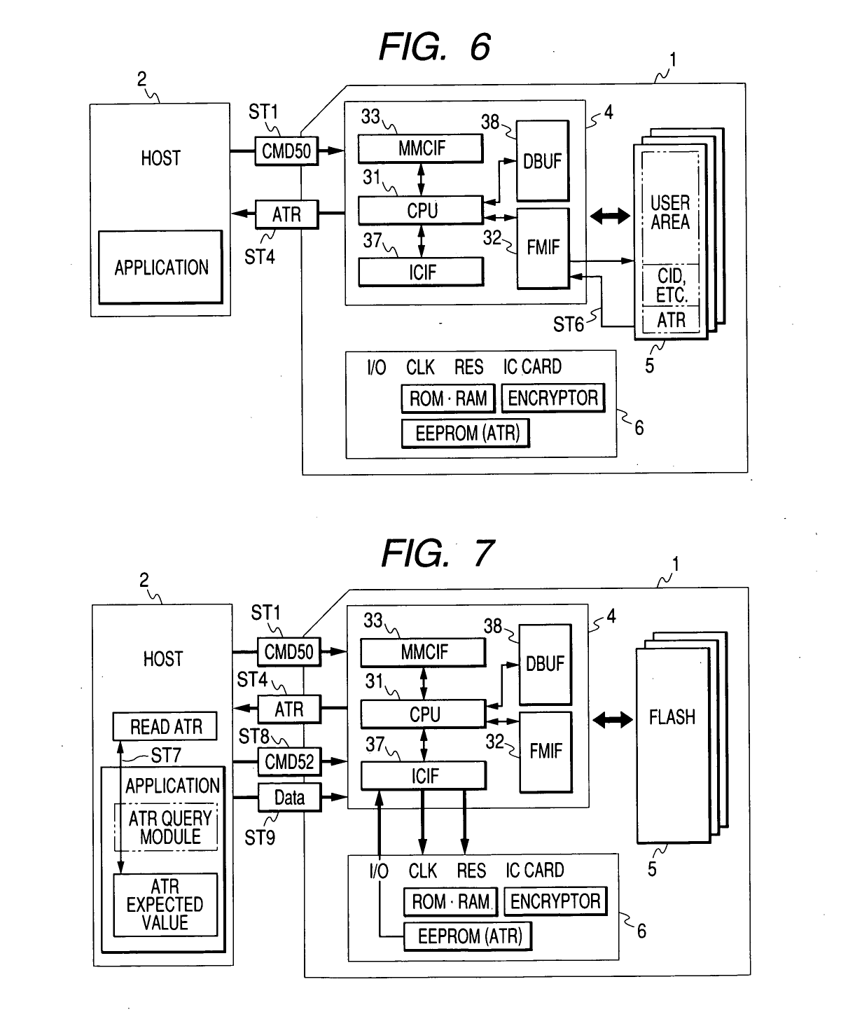

A third embodiment for realizing a function based on ATR information read command CMD50 is illustrated in FIG. 6. The third embodiment aims to store ATR information into a predetermined area of a corresponding flash memory chip 5 in advance, and when the ATR information read command CMD50 is accepted, read the ATR information from the flash memory chip 5 and output it to a host device 2. That is, control data such as CID and ATR information have previously been stored into a system area (area in which free usage is not granted to a user for an MMC1) different from a user area of each flash memory chip 5. When the ATR information read command CMD50 is issued from the host device 2 (ST1), a controller chip 4 inputs it therein, decodes it through a CPU 31, reads ATR information through an FMIF 32 and stores it into a data buffer 38 (ST6). Then, the CPU 31 outputs the ATR information from the data buffer 38 to the host device 2 through an MMCIF 33 (ST4). In the third embodiment, latency time from the issuance of the ATR information read command CMD50 from the host device 2 to the output of the ATR information from the MMCIF 33 to the host device 2 becomes short as compared with the first embodiment but becomes longer than in the second embodiment.

Incidentally, although not shown in the drawing, the example of FIG. 6 may be configured in such a manner that the reading of ATR information from the flash memory chip 5 to the data buffer 38 is executed in accordance with an initialization command based on CMD1 and thereafter the ATR information is outputted from the data buffer 38 to the outside in response to the command CMD50 in a manner similar to the case shown in FIG. 5.

An operation example in which a host device refers to ATR information is shown in FIG. 7. When the host device 2 executes an query module of ATR information in a host application program thereof, the host device 2 issues an ATR information read command CMD50 (ST1). An MMC1 responds to it and a controller chip 4 outputs ATR information to the host device 2 (ST4). The host device 2 determines whether the ATR information read in accordance with the program of the query module corresponds to one for an IC card OS specified by its expected information (ST7). When it is found to be the expected one for the IC card OS, the host device 2 issues a secure write command CMD52 (ST8) and instructs an IC card chip 6 to perform a predetermined security process. For example, the host device 2 makes a decision as to an encryption processing system mounted to the IC card chip in accordance with ATR information corresponding to the IC card OS. When the determined system is found to be an encryption processing system based on an elliptic cipher computation, the host device 2 gives instructions for an operation commensurate with write data (Data) following the security write command CMD52 in accordance with the write data (ST9).

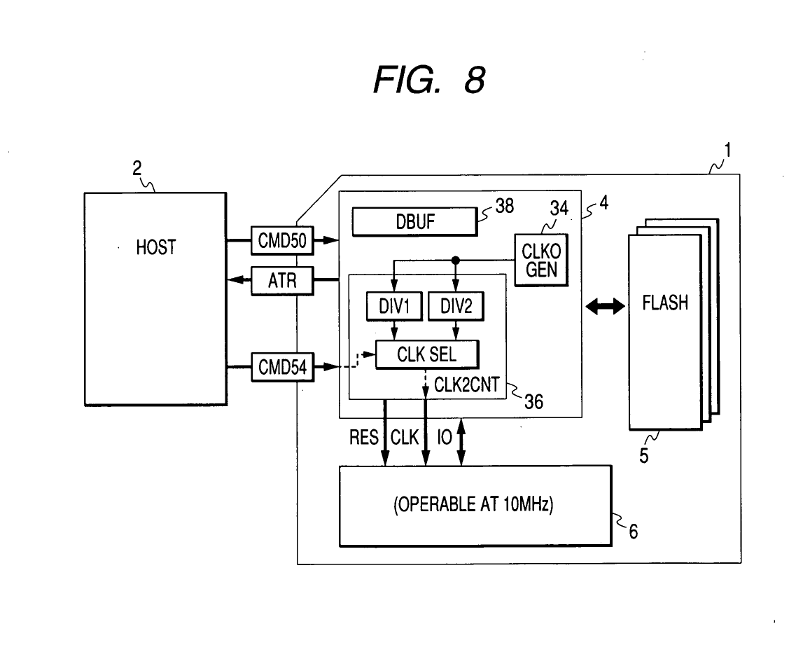

Another operation example in which a host device refers to ATR information, is shown in FIG. 8. It is desired that when the host device 2 is such a portable terminal as operated by a battery power supply, for example, an operating frequency of an IC card chip 6 is made low in terms of economizing power consumption. It is desired that when the host device 2 is a stationary terminal device operated by a commercial power source, which is capable of performing a balance inquiry or the like, the operating frequency of the IC card chip 6 is made high in terms of speeding-up of processing. It is also desired that since the supply of electric power to the IC card chip 6 is also covered by an electromotive force produced via an antenna when the host device 2 performs non-contact interface communication with the IC card chip 6, data processing is completed quicker. At this time, the host device 2 refers to operable frequency information of the IC card chip 6, contained in ATR information read in accordance with an ATR information read command CMD50. If the host device 2 is of a portable terminal, then the host device 2 sets a frequency lower than the highest operating frequency thereof to the IC card chip 6 in accordance with an operating frequency setting command CMD54. If the host device 2 is of a stationary terminal device, then the host device 2 sets the operating frequency of the IC card chip 6 to the highest operating frequency in accordance with the operating frequency setting command CMD54. If the host device 2 is of a device which performs interface in the form of noncontact with the IC card chip, then the host device 2 sets the operating frequency of the IC card chip 6 to the highest operating frequency in accordance with the operating frequency setting command CMD54. Incidentally, the IC card operating frequency setting command CMD54 is of a new or novel command which avails of an empty or free command code of a standard memory card command. A CLK2CNT 36, which performs the frequency control, has dividers DIV1 and DIV2 each of which divides a clock generated by a CLK0GEN 34, and a clock selector CLKSEL which selects the outputs of the dividers DIV1 and DIV2. When the highest operating frequency of the IC card chip 6 is assumed to be 10 MHz (Megahertz), the output of the divider DIV1 is set to 10 MHz and the output of the divider DIV2 is set to 1 MHz. The selection of the output by the clock selector CLKSEL is designated by the corresponding command CMD54. When the host device 2 desires to refer to read ATR information and operate the IC card chip at the highest operating frequency graspable from the ATR information, the host device 2 causes the IC card chip to select the output of the divider DIV1 in accordance with the command CMD54. When the host device 2 does not desire to operate the IC card chip at the highest operating frequency graspable from the ATR information, the host device 2 causes the IC card chip to select the output of the divider DIV2.

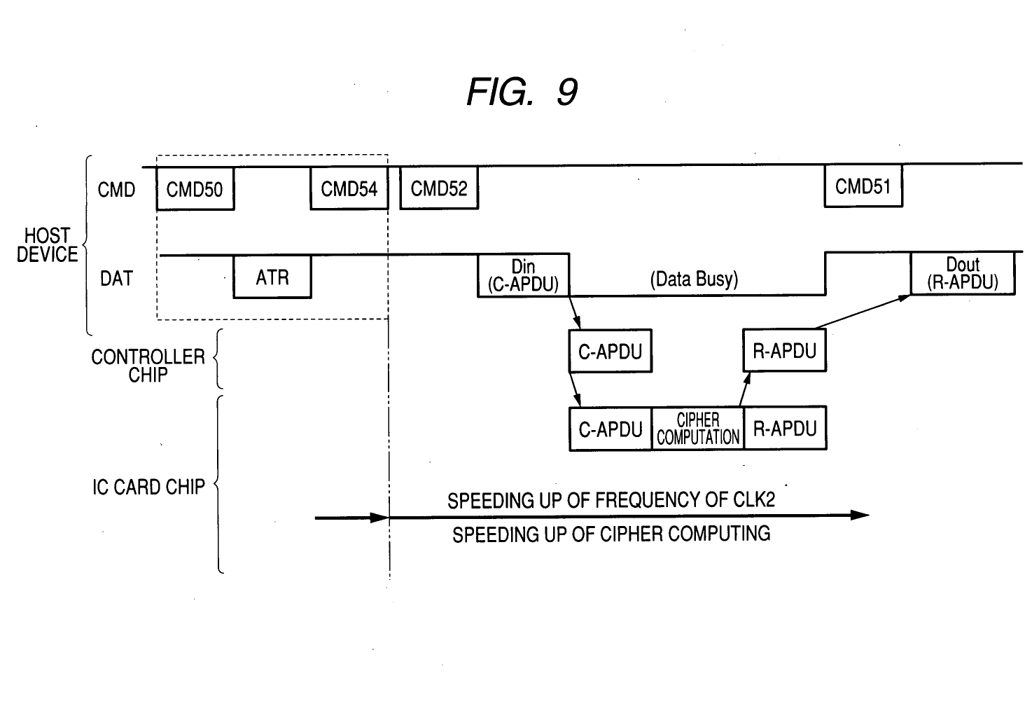

A further example in which a host device 2 refers to ATR information, is shown in FIG. 9. The host device 2 controls an operating frequency of an IC card chip 6 according to the contents of operation relative to the IC card chip 6 which conforms to an application program. When, for instance, the host device 2 causes the IC card chip 6 to execute a cipher computation in accordance with the application program, the host device 2 issues the command CMD50 to read ATR information. Then, the host device 2 causes a controller chip 4 to control the operating frequency of the IC card chip 6 in accordance with a command CMD54 in such a way as to activate the IC card chip 6 at a limit operating frequency indicated by the read ATR information. The control on the operating frequency with respect to the IC card chip 6 can be carried out by the output selection of each divider as described in FIG. 8, for example. Thereafter, the host device 2 writes an IC card command for a cipher computation into the controller chip 4 as an IC command (C-APDU) in accordance with a command CMD52. The controller chip 4 supplies the IC card command (C-APDU) for the cipher computation to the IC card chip 6. The IC card chip 6 decodes the IC card command (C-APDU) for the cipher computation and performs cipher computing (processing) in accordance with the result of decoding, and sends back a response (R-APDU) to the result of cipher computation to the host device 2. The response is outputted from a DAT terminal of an MMC1 to the host device 2 via the controller chip 4 in response to a command CMD51 supplied from the host device. Upon this operation, the cipher computing processing of the IC card chip 6 is executed at high speed in sync with the limit operating frequency of the IC card chip 6 or a high frequency commensurate with it. In brief, the host device grasps settable operating capability such as the limit operating frequency of the IC card chip 6 in accordance with the ATR information read command CMD50.

Correspondingly, the host device can effect the setting of making the processing efficient on the IC card chip 6 in terms of the property of the operation of using the IC card chip 6 as typified by the speeding up of a synchronous clock frequency for cipher computation. Thus, it is possible to speed up the processing operation of the MMC1 in accordance with the processing based on the application program of the host device 2 as typified by the cipher computing processing of the IC card chip 6. When a command system for reading the ATR information of the IC card chip 6 is not prepared for the host device 2 as in the prior art, the host device 2 is not capable of performing command processing surrounded with a broken line of FIG. 9 and performing the control that the cipher computing processing of the IC card chip 6 is designated to speed up its operation. Thus, the period necessary for execution of the cipher computing processing in FIG. 9 becomes long.

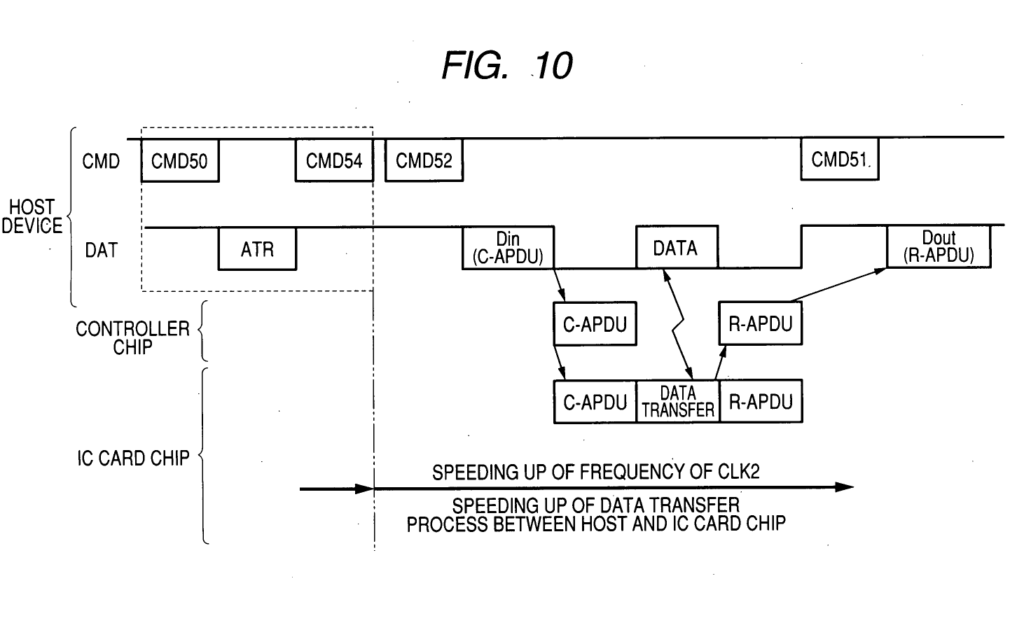

A still further example in which a host device 2 refers to ATR information, is shown in FIG. 10. In a manner similar to FIG. 9, the host device 2 controls an operating frequency of an IC card chip 6 in accordance with the contents of operation relative to the IC card chip 6 which conforms to an application program. In the present example, the clock signal frequency of the IC card chip 6 is set high when the transfer of data is performed between the host device 2 and the IC card chip 6. When the host device 2 performs the transfer of data to and from the IC card chip 6, the host device 2 issues the command CMD50 to read ATR information. Then, the host device 2 causes a controller chip 4 to speed up the operating frequency of the IC card chip 6 in accordance with a command CMD54 in such a manner as to operate the IC card chip 6 at a limit operating frequency indicated by the read ATR information. Thus, it is possible to speed up the transfer of data between the host device 2 and the IC card chip 6 in large capacity. When a command system for reading the ATR information of the IC card chip 6 is not prepared for the host device 2 as in the prior art, the host device 2 is not capable of performing command processing surrounded with a broken line of FIG. 10 and increasing the operating frequency of the IC card chip 6. Thus, long time is necessary for the processing for the transfer of data between the host device 2 and the IC card chip 6.

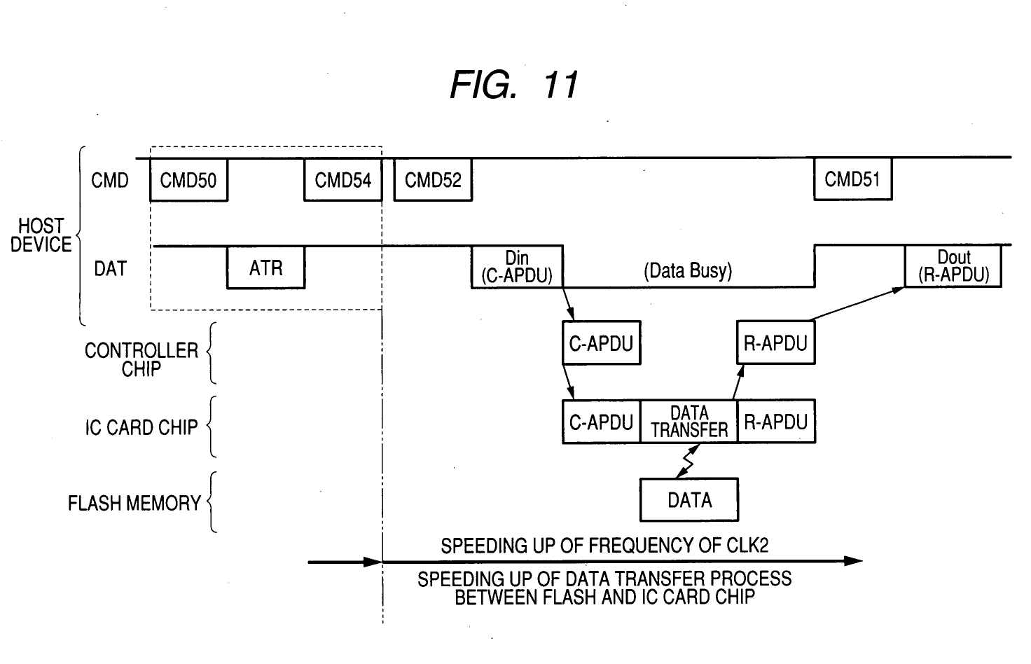

A still further example in which a host device 2 refers to ATR information, is shown in FIG. 11. In a manner similar to FIG. 9, the host device 2 controls an operating frequency of an IC card chip 6 in accordance with the contents of operation relative to the IC card chip 6 which conforms to an application program. In the present example, the clock signal frequency of the IC card chip 6 is set high when the transfer of data is performed between the IC card chip 6 and a flash memory chip 5. When the host device 2 performs the transfer of data between the IC card chip 6 and the flash memory chip 5, the host device 2 issues the command CMD50 to read ATR information. Then, the host device 2 causes a controller chip 4 to speed up the operating frequency of the IC card chip 6 in accordance with a command CMD54 in such a manner as to operate the IC card chip 6 at a limit operating frequency indicated by the read ATR information. Thus, it is possible to speed up the transfer of data between the IC card chip 6 and the flash memory chip 5 in large capacity. When a command system for reading the ATR information of the IC card chip 6 is not prepared for the host device 2 as in the prior art, the host device 2 is not capable of performing command processing surrounded with a broken line of FIG. 11 and increasing the operating frequency of the IC card chip 6. Thus, long time is required for the processing for the transfer of data between the IC card chip 6 and the flash memory chip 5.

<<Command for Reading Information Indicative of Erase Unit>>

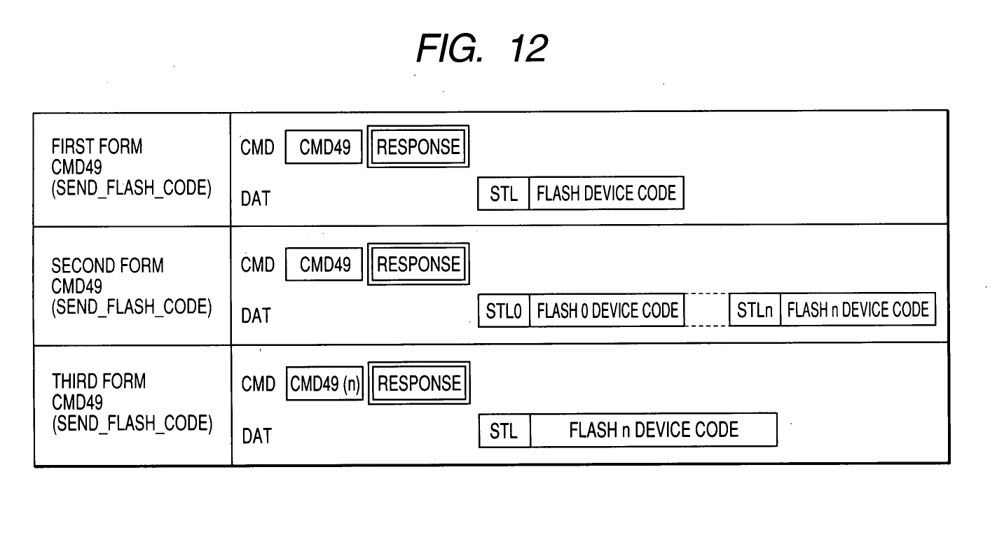

Several forms of read commands for device codes (device code read commands) stored in each flash memory chip 5 as information indicative of erase units are illustrated in FIG. 12. The device codes are defined as code information each indicative of the type of product for each manufacturer of a flash memory. According to each device code, the storage capacity of the corresponding flash memory 5 and the number of bytes of each erase unit are uniquely recognized.

The first form of the device code read command is defined as a new or novel command CMD49 which avails of an empty or free command code of a standard memory card command. Signal information corresponding to the described position of CMD in the column of the device code read command CMD49 means signal information inputted/outputted via the CMD terminal. Signal information corresponding to the described position of DAT means signal information inputted/outputted via the DAT terminal. In the figure, the direction of supply of information described in a single or onefold frame corresponds to the direction of the MMC1 as viewed from the card host. The direction of supply of information described in a double frame corresponds to the direction of the card host as viewed from the MMC1. When the command CMD49 is inputted to the CMD terminal, a response is sent back in response to the command CMD49 and a device code (flash device code) of the corresponding flash memory chip 5 is outputted to the DAT terminal following the number of transfer data bytes STL. The first form is set assuming that the flash memory chip 5 is single.

The second form of the device code read command is set assuming that the flash memory chip 5 mounted to the MMC1 is made up of a plurality of memory chips. A data output from the DAT terminal, which responds to the CMD49, is constituted as a sequential output of the number of data bytes STL and a flash device code for each flash memory chip 5. The number of flash memory chips 5 is recognized by the controller chip 4, which controls data outputs corresponding to the number thereof.

The third form of the device code read command is set so as to read a flash device code of one flash memory chip 5 designated by a parameter where the number of the flash memory chips 5 mounted to the MMC1 is two or more. The parameter is information which designates to what number of flash memory chips the flash memory chip corresponds. The controller chip 4 outputs a flash device code of a flash memory chip corresponding to the number designated by the parameter with respect to the number of the flash memory chips from the DAT terminal. The third form has the significance of being used where an attempt to read individual flash device codes one by one is made when the plurality of flash memory chips 5 are mounted.

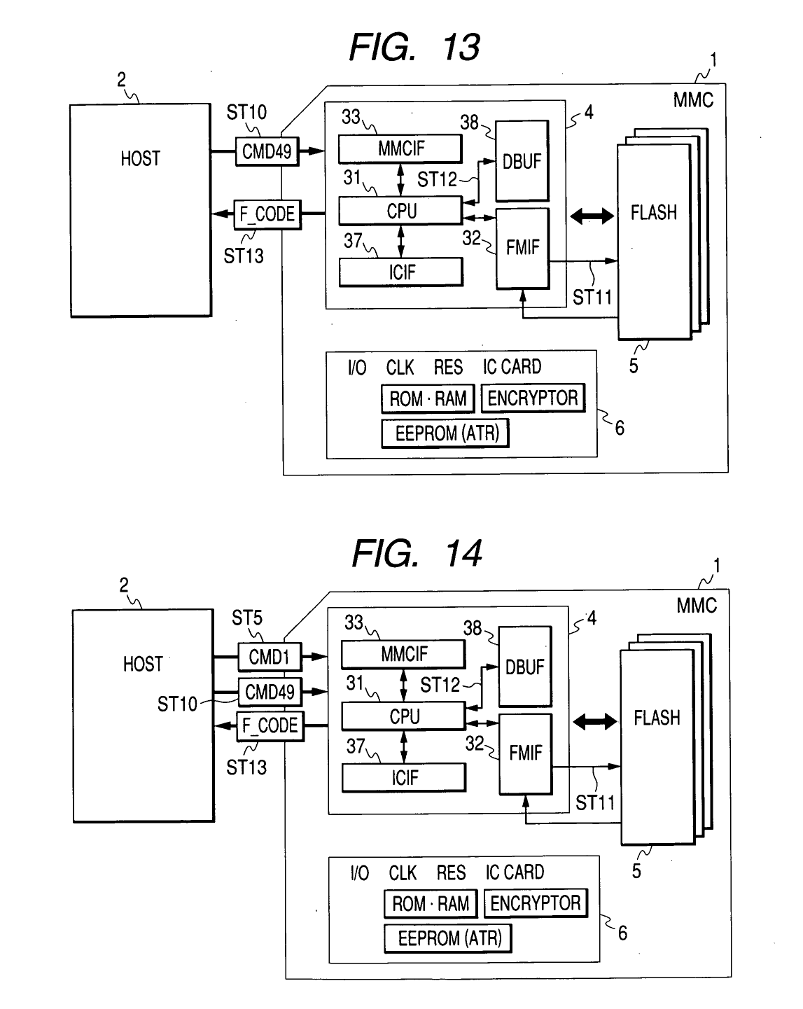

A first embodiment for realizing a function based on a device code read command CMD49 is illustrated in FIG. 13. In the first embodiment, when a host device 2 issues the device code read command CMD49 (ST10), a controller chip 4 issues a device code output command to its corresponding flash memory chip 5 (ST11) and thereby stores the flash device code read from the flash memory chip 5 in a data buffer 38 (ST12), and outputs the stored flash device code to the host device 2 (ST13). F_CODE is a flash device code outputted from an MMC1.

A second embodiment for realizing a function based on a device code read command CMD49 is illustrated in FIG. 14. The second embodiment aims to read a flash device code from a corresponding flash memory chip 5 by reset processing upon power-on reset of an MMC1 and store it into a data buffer 38, and output the flash device code from the data buffer 38 to a host device 2 when the device code read command CMD49 is accepted. That is, when a reset startup command CMD1 is issued from the host device 2 (ST14), a controller chip 4 inputs it therein and decodes it through a CPU 31, and gives a device code output command to the flash memory chip 5 via an FMIF 32 (ST11). Thus, the controller chip 4 stores and holds the flash device code read from the flash memory chip 5 in the data buffer 38 through the CPU 31 (ST12). Thereafter, when the corresponding device code read command CMD49 is issued from the host device 2 (ST10), the controller chip 4 inputs it therein and decodes it through the CPU 31, and outputs the flash device code stored in the data buffer 38 from an MMCIF 33 to the host device 2 (ST13). In the second embodiment as compared with the first embodiment, latency time from the issuance of the device code read command CMD49 from the host device 2 to the output of the flash device code to the host device 2 through the MMCIF 33 becomes short.

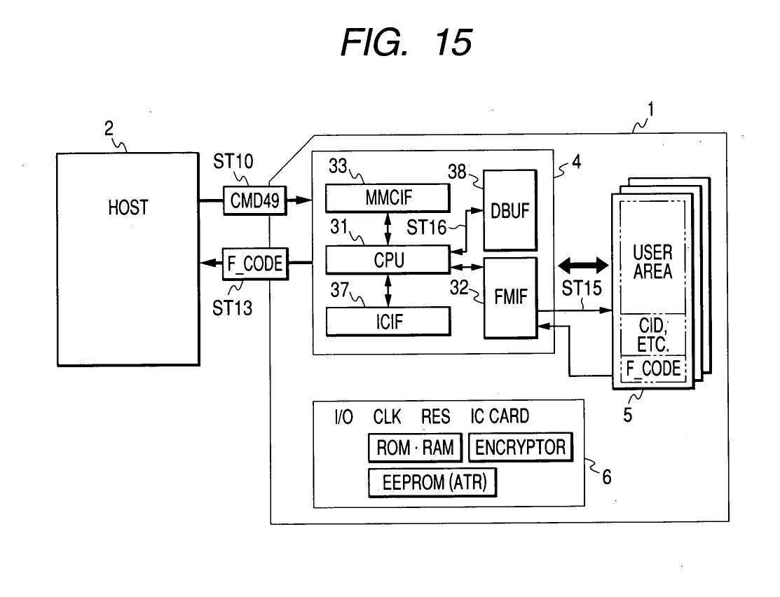

A third embodiment for realizing a function based on a device code read command CMD49 is illustrated in FIG. 15. The third embodiment aims to store a flash device code F_CODE into a predetermined memory area of a corresponding flash memory chip 5 in advance, and when the device code read command CMD49 is accepted, read the flash device code from the flash memory chip 5 in accordance with a memory access command for reading the flash device code and output it to a host device 2. That is, control data such as CID and the flash device code F_CODE have previously been stored into a system area different from a user area of each flash memory chip 5. This area is defined as a memory area different from a storage area of a device code individually held in each flash memory chip 5. Thus, when a plurality of flash memory chips 5 exist, device codes of all the flash memory chips are typically stored in the predetermined area of one flash memory chip. When the corresponding device code read command CMD49 is issued from the host device 2 (ST10), a controller chip 4 inputs it therein, decodes it through a CPU 31, and gives a memory access command for reading a device code to the corresponding flash memory chip 5 via an FMIF 32 (ST15), thereby storing the read flash device code into a data buffer 38 (ST16). Then, the CPU 31 outputs the flash device code from the data buffer 38 to the host device 2 through an MMCIF 33 (ST13). In the third embodiment, latency time from the issuance of the device code read command CMD49 from the host device 2 to the output of the flash device code from the MMCIF 33 to the host device 2 becomes short as compared with the first embodiment but becomes longer than in the second embodiment.

Incidentally, although not shown in the drawing, the example of FIG. 15 may be configured in such a manner that the reading of the flash device code from the flash memory chip 5 to the data buffer 38 is executed in accordance with an initialization command based on CMD1 and thereafter the flash device code is outputted from the data buffer 38 to the outside in response to the command CMD49 in a manner similar to the case shown in FIG. 14.

A description will next be made of the operation of writing data into an MMC1 by a host device 2. Prior to the description of a use form of a flash device code, a description will be made of a case in which differences in the number of writings and write processing time occur according to the contents of instructions by write command processing due to a difference in erase unit of each flash memory chip.

When instructions as to multiwrite for writing data continuously are given to the MMC1, the host device 2 sets the number of write data in 512 byte units in accordance with a command CMD23 and thereafter supplies a command CMD25 and write data to give instructions as to the start of a write operation. Accordingly, a difference occurs in the number of erasures due to the relationship between the designated number of write data and erase units. When data of 1 kilobyte (KB) is transferred with one write command, for example, a write command is issued twice in total where data of 2 KB is written into an AND type flash memory with an erase unit as 2 KB, and hence erasure is required twice with respect to one erase unit. When data of 4 KB is written into an AG-AND type flash memory with an erase unit as 4 kilobytes (KB), a write command is issued four times in total and hence erasure is required four times with respect to one erase unit. Similarly, when data of 16 KB is written into a NAND type flash memory with an erase unit as 16 kilobytes (KB), a write command is issued sixteen times in total and hence erasure is required sixteen times with respect to one erase unit.

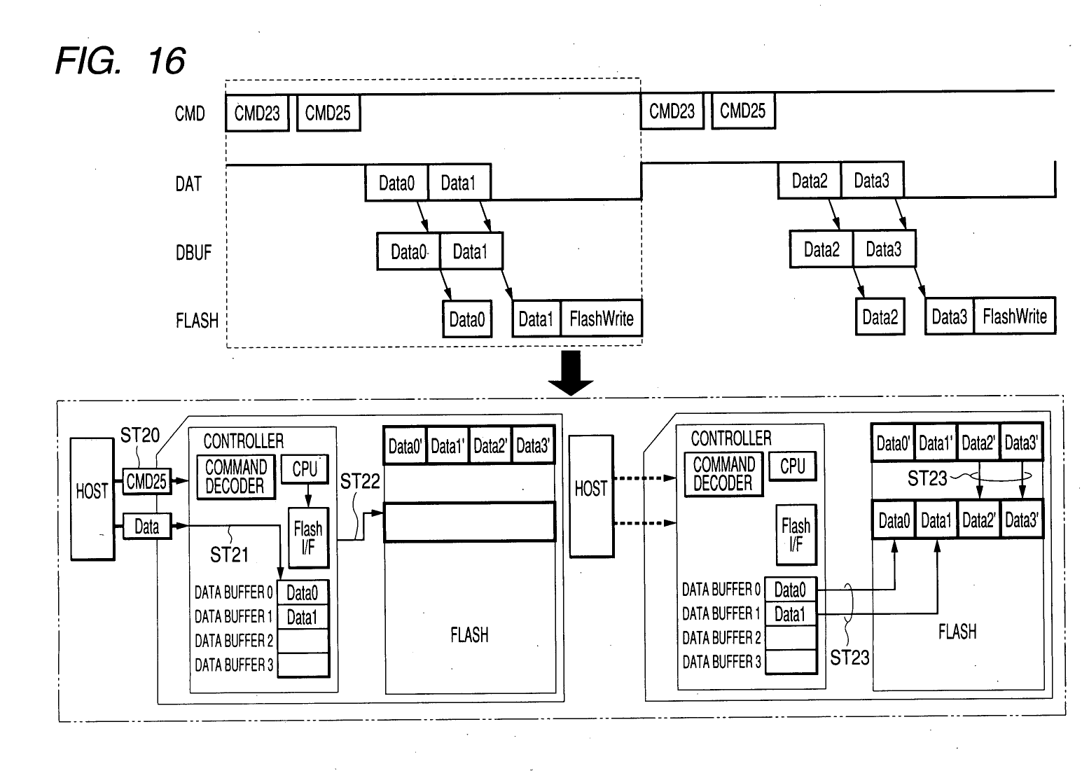

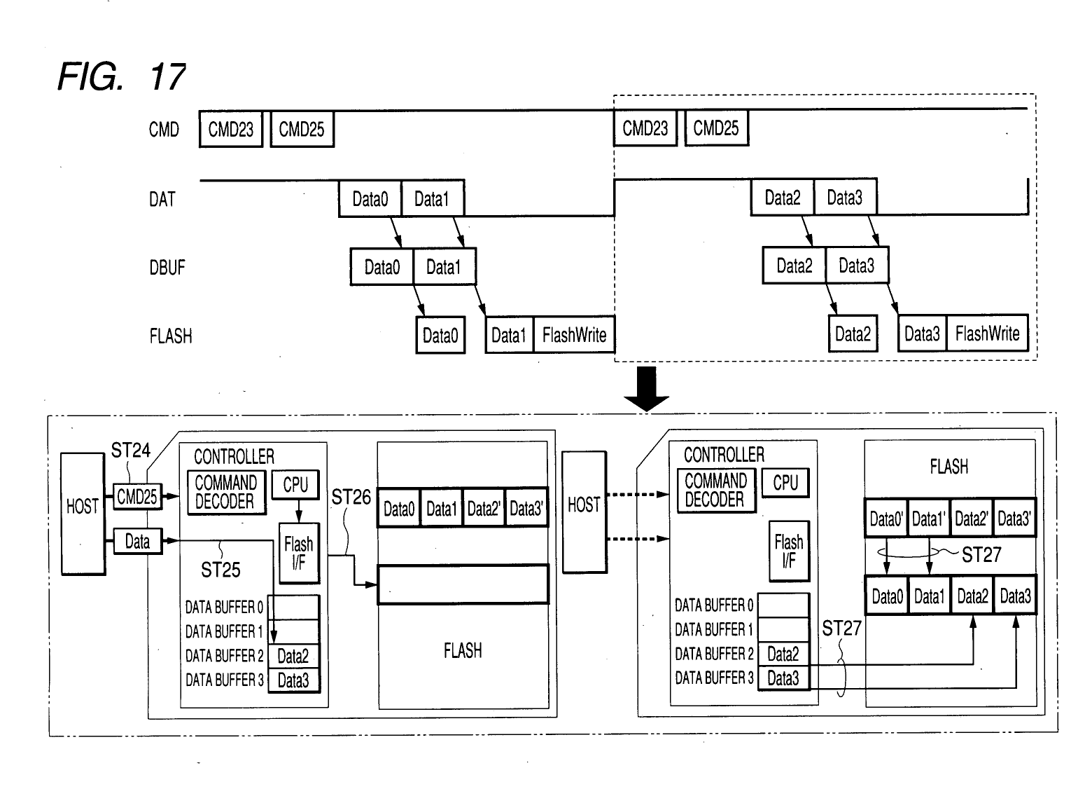

Consider where, for example, data of 1 KB is transferred to an MMC1 with a flash memory having an erase unit of 2 KB mounted thereto, with one command and data of 2 KB in total is written. When a write command CMD25 and write data Data0 and Data1 set in 512 byte units are supplied from a host device as shown in FIG. 16 (ST20), the transferred data Data0 and Data1 (512B×2) are fetched in data buffers (ST21). When an effective physical address corresponding to a logical address where writing is made, exists, a new physical address to which the logical address is allocated, is retrieved and a block for the retrieved new write-target physical address is erased (ST22). 1 KB write data Data0 and Data1 stored in data buffers and the remaining 1 KB data Data2′ and Data3′ for the original physical addresses to which physical addresses intended for writing have been allocated, are written into the erased write-target physical address (ST23). When a write command CMD25 and the remaining write data Data2 and Data3 set in 512 byte units are next supplied from the corresponding host device as shown in FIG. 17(ST24), the transferred data Data2 and Data3 (512B×2) are fetched into their corresponding data buffers (ST25). When an effective physical address corresponding to a logical address where writing is made, exists, a new physical address to which the logical address is allocated, is retrieved and a block for the retrieved new write-target physical address is erased (ST26). 1 KB write data Data2 and Data3 stored in data buffers and the remaining 1 KB data Data0 and Data1 for the original physical addresses to which physical addresses intended for writing have been allocated, are written into the erased write-target physical address (ST27). Thus, when the new write data based on one write command is 1 KB, erasure of 2 blocks is needed with respect to the flash memory with the erase unit as 2 KB.

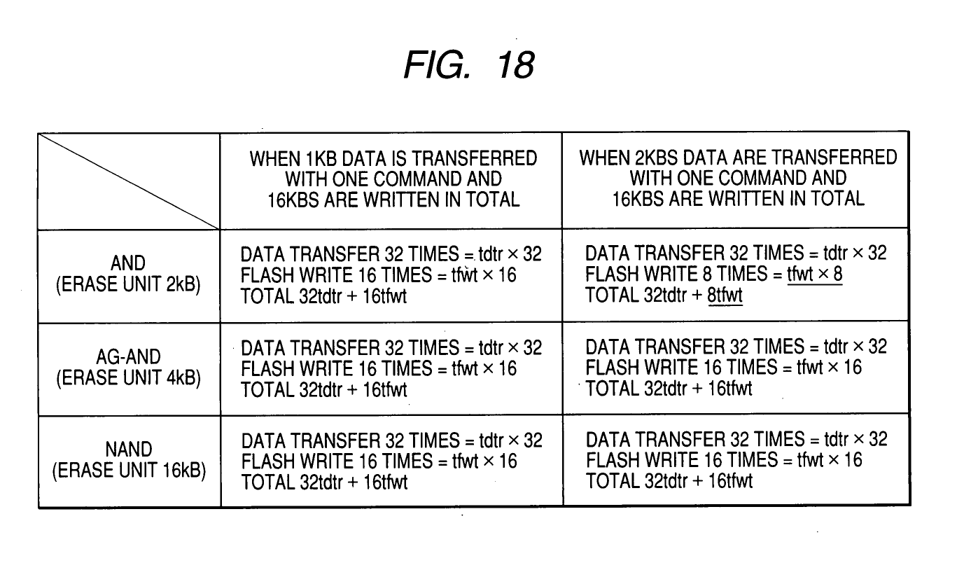

Also a difference occurs even in write time depending on the number of transfer data per one write command. When a comparison is made between a case in which write data of 1 KB is transferred with one write command and writing of 16 KB in total is done and a case in which write data of 2 KB is transferred with one write command and writing of 16 KB in total is done, as illustrated in FIG. 18 by way of example, the total time required to transfer data in 512 byte units becomes constant like tdtr×32 despite of an erase unit. However, a difference occurs between time intervals necessary for erase and write processes for each flash memory. In order to perform writing of 16 KB in total with respect to the flash memory with the erase unit as 2 KB, the transfer of the write data of 2 KB for each write command is most efficient.

Thus, the differences occur in the number of erasures and write processing time depending on the contents of instructions by the write command processing due to the difference in erase unit of each flash memory chip. If the host device grasps the erase unit of the flash memory and transfers the write data in view of above, it is then possible to reduce the number of erasures relative to one erase unit and suppress a needless increase in write processing time. The host device 2 grasps the erase unit of the corresponding flash memory chip 5 from the flash device code read by the device code read command CMD49.

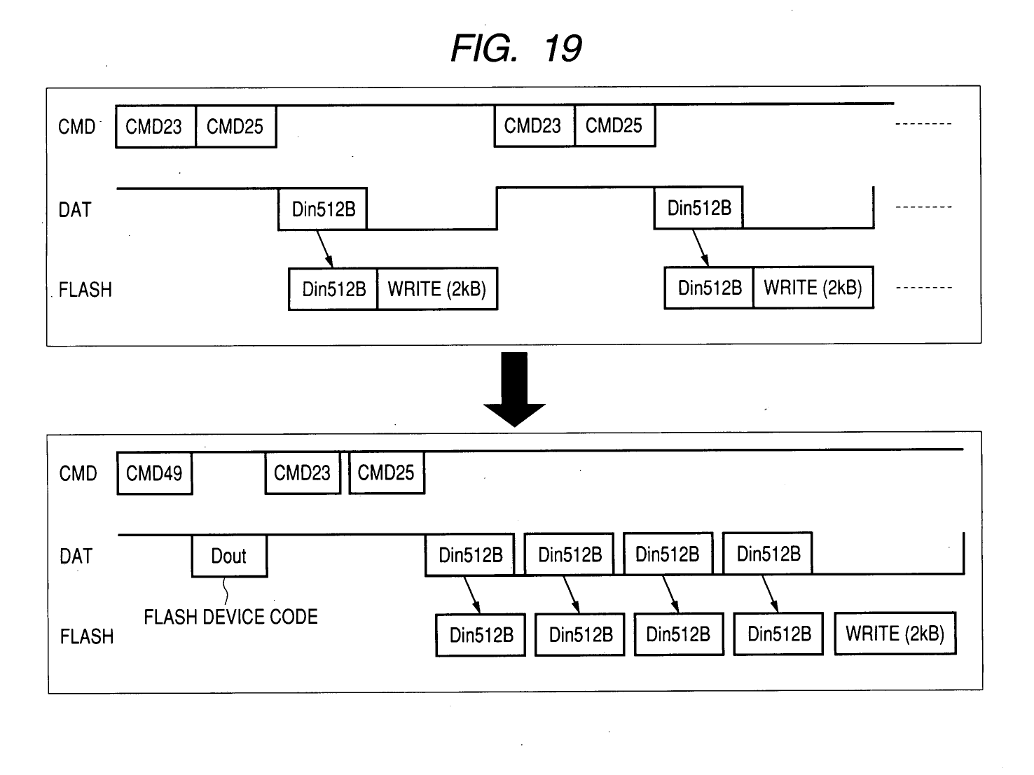

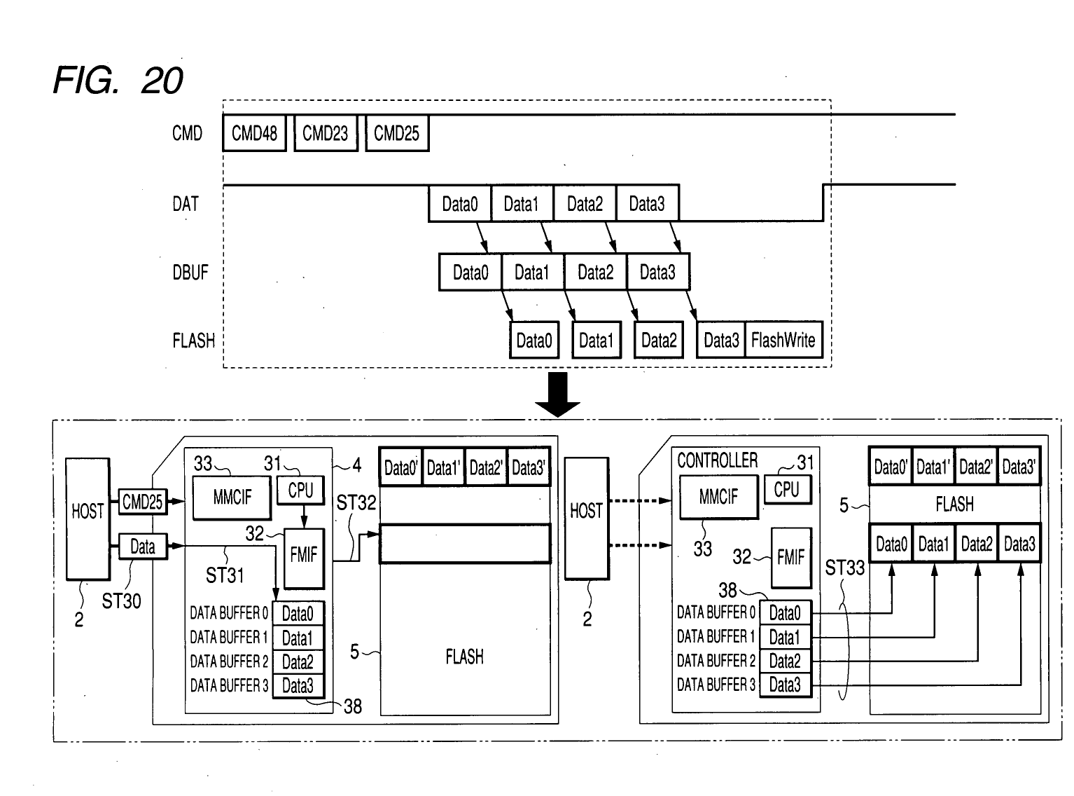

An example of the operation of causing a host device 2 to grasp an erase unit of a flash memory chip 5 from a flash device code and optimizing the number of transfers of write data is shown in FIG. 19. When writing is done in 512B units with respect to a flash memory chip 5 with an ease unit as 2 KB, there is a need to repeat the issuance of a write command, and erase and write operations four times. On the other hand, if the host device 2 grasps an erase unit of a flash memory chip 5 from a flash device code read by a device code read command CMD49, then the host device 2 grasps that the issuance of the write command from the host device 2 and the erase and write operations of the flash memory chip 5 can be completed once if writing is done in 2 KB units in the case of the flash memory chip 5 with the ease unit as 2 KB. Correspondingly, write data of 512 bytes is transferred four times and write processing is completed with one 2 KB writing.

The operation of transferring, with one command, data of 2 KB to an MMC1 to which a flash memory chip 5 with an erase unit of 2 KB is mounted, and writing data of 2 KB in total is shown in FIG. 20. Prior to the write operation, a host device 2 grasps based on a command CMD49 that the erase unit of the flash memory chip 5 mounted to the MMC1 is 2 KB.

When a write command CMD25 and write data Data0, Data1, Data2 and Data3 set in 2 KB byte units are supplied from a host device 2 (ST30), the transferred data Data0, Data1, Data2 an Data3 (512B×4) are fetched in data buffers 38 (ST31). When an effective physical address corresponding to a logical address where writing is made, exists, a new physical address to which the logical address is allocated, is retrieved and a block for the retrieved new write-target physical address is erased (ST32). 2 KB write data Data0, Data1, Data2 and Data3 stored in data buffers are written into the erased write-target physical address (ST33). Write processing is completed in this way.

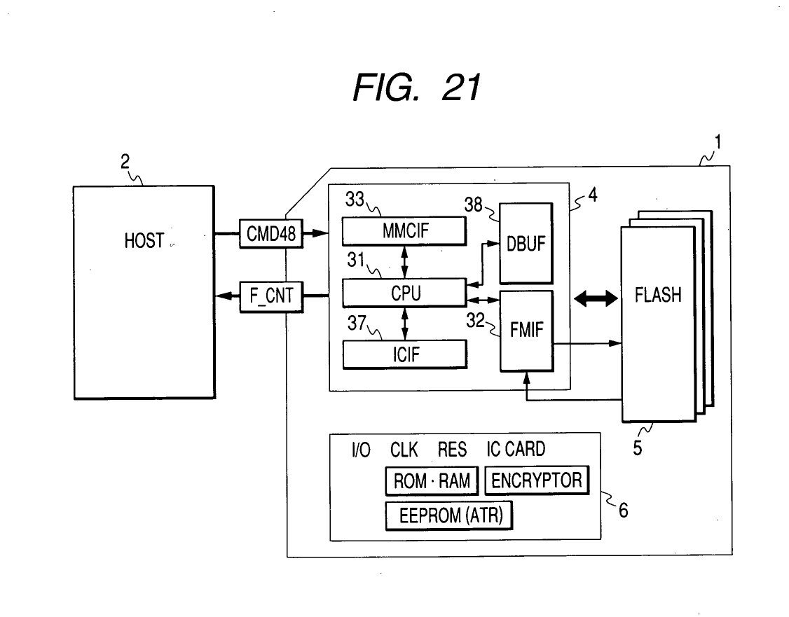

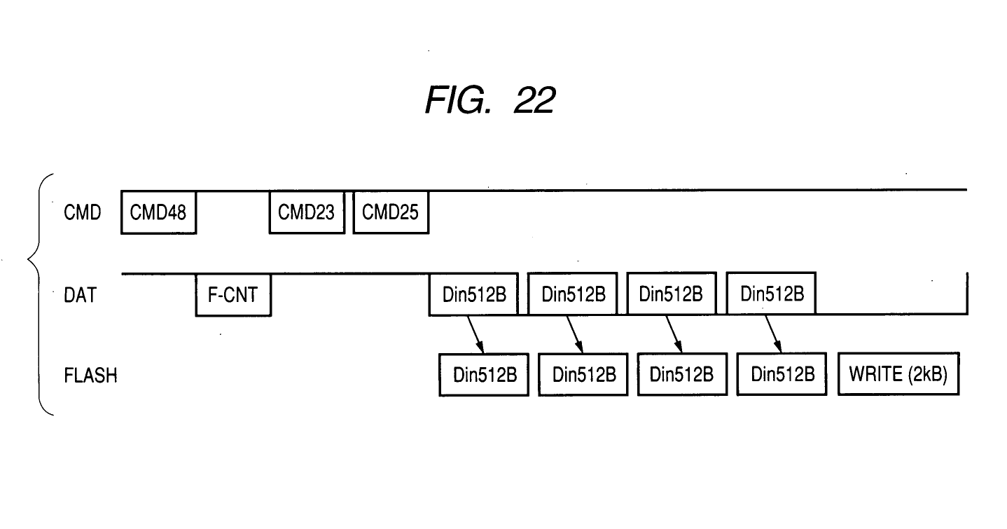

An example in which a controller chip 4 has the function of analyzing the optimum rewrite or reprogrammable unit based on a read device code, is shown in FIG. 21. When an optimum rewrite unit read command CMD48 is supplied from a host device 2 (ST40), a controller chip 4 decodes the command CMD48 through a CPU 31 and instructs a flash memory chip 5 to read a flash device code (ST41). The controller chip 4 acquires an erase unit from the flash device code read from the flash memory chip 5 and analyzes the optimum rewrite unit. The optimum rewrite unit is 2 KB where a device is of a flash memory chip 5 with an erase unit as 2 KB, for example. The result of analysis may be such a value like 2 KB or may be the number of data, e.g., 4 with 512B as a data unit. The result of analysis is retained in a data buffer 38 (ST42). Thereafter, the CPU 31 outputs the optimum rewrite unit information held in the data buffer 38 to the host device 2. The host device 2 determines the number of data coming with one write command by directly referring to the optimum rewrite unit information and issues a write command to an MMC1. In an example of FIG. 22, for example, F_CNT is the optimum rewrite unit information and is defined as a value 4. The value 4 means 512B×4. Write data following a write command CMD25 are configured with Din512B of 512B as four units and defined as 2 KB in total. Erase and write processing for the flash memory chip 5 with the erase unit as 2 KB can be carried out most efficiently.

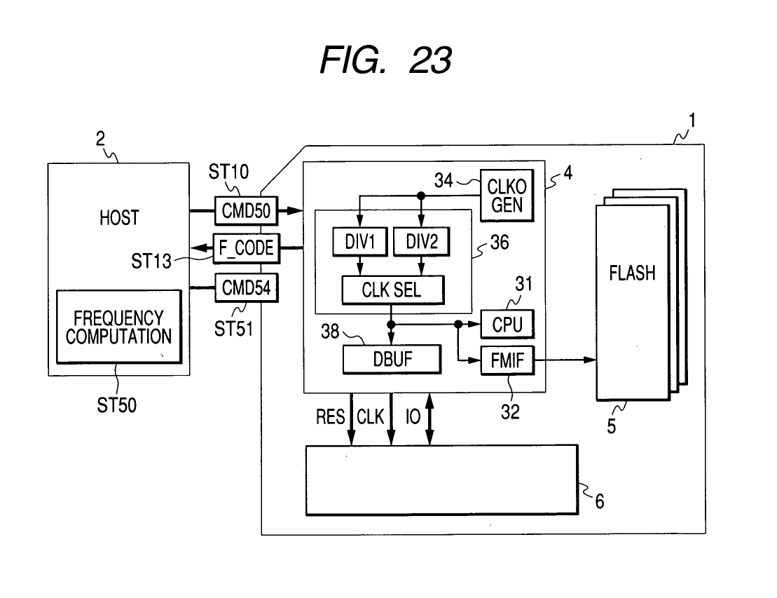

An example in which a device code is used to set the frequency of each of flash memory chips 5, is shown in FIG. 23. When a device code read command CMD49 is issued from a host device 2 (ST10) and a flash device code F_CODE responsive to it is outputted to the host device 2 (ST13), the host device 2 calculates an operation limit frequency of the corresponding flash memory chip 5 from the flash device code (ST50) and issues a command CMD54 for setting the operating frequency of the flash memory chip 5 (ST51). When the controller chip 4 receives the command CMD54, the controller chip 4 controls the operating frequencies of a CPU 31, a DBUF 38 and a corresponding flash memory chip 5 through a CLK2CNT 36. Although the operating frequency of the IC card chip 6 has been set by the CLK2CNT 36 in the description of FIG. 8, the CLK2CNT 36 has dividers DIV1 and DIV2 which divide a clock generated by a CLK0GEN 34, and a clock selector CLKSEL which selects the outputs of the dividers DIV1 and DIV2 in the present example. Assuming that the highest operating frequency of the flash memory chip 5 is 10 MHz (Mega Hertz), for example, the output of the divider DIV1 is set to 10 MHz and the output of the divider DIV2 is set to 1 MHz. The selection of the output by the clock selector CLKSEL is designated by the command CMD54. When the host device 2 desires to refer to a read flash device code and operate the flash memory chip 5 at the highest operating frequency graspable therefrom, the host device 2 causes the command CMD54 to select the output of the divider DIV1. When the host device 2 does not desire to operate the IC card chip at the highest operating frequency graspable from the device code, the host device 2 causes the command CMD54 to select the output of the divider DIV2. Incidentally, since the DBUF 38 is operated in sync with a clock as in a synchronous DRAM, its operating clock frequency is also controlled in sync with the operating frequencies of the flash memory chip 5 and the CPU 31.

Although so even in the case of FIG. 8, the dividers typified by two are changed to variable dividers and their division ratios may be controlled so as to be variable programmably arbitrarily or in multistage in accordance with a command.

Although not shown in the drawing in particular, the controller chip 4 may be configured so as to read the flash device code F_CODE from the corresponding flash memory chip 5 in response to a predetermined command like an operation limit frequency read command, calculate the operating limit frequency of the flash memory chip 5 from the read flash device code and output the calculated operating limit frequency to the host device 2. When the host device 2 issues a command CMD54 for setting the operating frequencies of the corresponding flash memory chip 5 or the like based on the operating limit frequency, the controller chip 4 controls the operating frequencies of the CPU 31, DBUF 38 and flash memory chip 5 by the CLK2CNT 36 in response to the command CMD54.

While the invention made above by the present inventors has been described specifically based on the embodiments, the present invention is not limited to the embodiments. It is needless to say that various changes can be made thereto within the scope not departing from the gist thereof.

For instance, the nonvolatile memory is not necessarily limited to the MMC. The present invention is widely available to various types of nonvolatile memories or storage devices of other memory card standards. Thus, a command code, a command format, a data communication protocol, etc. can be changed in various ways in conformity with the card standards. Also the interface controller, security controller and nonvolatile memory are not limited to discrete chips respectively. For instance, the interface controller and nonvolatile memory may be configured as one chip or all may be configured as one chip. Further, the security controller is not limited to the IC card microcomputer but may be a circuit module having a security function, which will be developed in the future or exists at present.

1. A nonvolatile memory comprising:
an interface controller;
a reprogrammable nonvolatile memory; and
a security controller which performs security processing of data,
wherein the interface controller is capable of outputting response information which is at least one of reset response information outputted by the security controller in response to a reset instruction to the security controller and information indicative of an erase unit of a storage area of the reprogrammable nonvolatile memory to the outside, in response to a first command supplied to the interface controller from outside.

2. The nonvolatile memory according to claim 1,
wherein the interface controller extracts security processing information contained in a second command supplied from outside, in response to the second command, and supplies the security processing information to the security controller, and
wherein the interface controller outputs the result of security processing by the security controller to the outside in response to a third command supplied from outside.

3. The nonvolatile memory according to claim 1, wherein the interface controller has a volatile memory circuit which latches said response information in response to a reset command of the nonvolatile memory and outputs the one information held in the volatile memory circuit to the outside of a memory card in response to the predetermined first command.

4. The nonvolatile memory according to claim 3, wherein said response information latched in the volatile memory circuit is read from the reprogrammable nonvolatile memory.

5. The nonvolatile memory according to claim 1, wherein the first command has a command code different from the reset command of the nonvolatile memory.

6. The nonvolatile memory according to claim 1,
wherein the first command corresponds to the reset command of the nonvolatile memory, and
wherein the interface controller outputs said response information to the outside following a response to reset processing.

7. The nonvolatile memory according to claim 1,
wherein the first command is a read command relative to a predetermined register held in the interface controller, and
wherein the interface controller outputs the response information to the outside together with information retained in the register.

8. The nonvolatile memory according to claim 1, wherein the reset response information of the security controller includes an operation limit frequency and historical byte information of the security controller.

9. The nonvolatile memory according to claim 1, wherein the information indicative of the erase unit of the storage area of the reprogrammable nonvolatile memory is a device code indicative of the type of reprogrammable nonvolatile memory, or number-of-data information corresponding to the erase unit, generated based on the device code.

10. The nonvolatile memory according to claim 1, wherein the interface controller is capable of changing the frequency of a clock signal supplied to the security controller in response to a frequency setting command.

11. A data processing system comprising:
a nonvolatile memory as defined in claim 1, which is mountable thereto,
wherein the first command for outputting the response information including the reset response information is outputted to the nonvolatile memory, the reset response information outputted from the nonvolatile memory is inputted in response to the first command, and the setting of an operating frequency of the security controller is changeable by reference to the inputted reset response information.

12. A data processing system comprising:
a nonvolatile memory as defined in claim 1, which is mountable thereto,
wherein the first command for outputting the response information including the information indicative of the erase unit of the storage area is outputted to the nonvolatile memory, the information indicative of the ease unit of the storage area, which is outputted from the nonvolatile memory, is inputted in response to the first command, and the number of transfers of write data to the nonvolatile memory is set for each erase unit, based on the inputted information indicative of the erase unit.

13. A nonvolatile memory comprising:
an interface controller; and
a reprogrammable nonvolatile memory,
wherein the interface controller is capable of outputting first information indicative of an erase unit of a storage area of the reprogrammable nonvolatile memory to the outside in response to a first command supplied to the interface controller from outside.

14. The nonvolatile memory according to claim 13,
wherein the first command is a reset command of the nonvolatile memory, and
wherein the interface controller performs reset processing of the nonvolatile memory itself and outputs the first information indicative of the erase unit to the outside following a response to the reset command.

15. The nonvolatile memory according to claim 13,
wherein the first command is a read command relative to a predetermined register held in the interface controller, and
wherein the interface controller outputs the first information indicative of the erase unit to the outside together with information retained in the register.

16. The nonvolatile memory according to claim 13, wherein the first information indicative of the erase unit is a device code indicative of the type of reprogrammable nonvolatile memory, or number-of-data information corresponding to an erase unit of a storage area, generated based on the device code.

17. The nonvolatile memory according to claim 13, wherein the interface controller acquires a device code indicative of the type of reprogrammable nonvolatile memory from the reprogrammable nonvolatile memory, acquires an operation limit frequency of the reprogrammable nonvolatile memory based on the acquired device code, and outputs the operation limit frequency to the outside in response to the first command.

18. The nonvolatile memory according to claim 17, wherein the interface controller is capable of changing the frequency of a clock signal supplied to the reprogrammable nonvolatile memory in response to a frequency setting command.
